(19) United States
(12) Patent Application Publication
(10) Pub. No.: US 2025/0374667 A1
(43) Pub. Date: Dec. 4, 2025

(54) SEMICONDUCTOR DEVICE AND MANUFACTURING METHOD OF SEMICONDUCTOR DEVICE

(71) Applicant: INSTITUTE OF SCIENCE TOKYO, Tokyo (JP)

(72) Inventors: Takayuki OHBA, Tokyo (JP); Shinji SUGATANI, Tokyo (JP)

(21) Appl. No.: 19/220,577

(22) Filed: May 28, 2025

(30) Foreign Application Priority Data
May 30, 2024 (JP) 2024-088222

(51) Int. Cl. H10D 84/85; H10D 84/01

(52) U.S. Cl. CPC H10D 84/856; H10D 84/0167; H10D 84/017; H10D 84/851

(57) ABSTRACT

A semiconductor device includes a substrate, and a first transistor including a first channel semiconductor layer provided on the substrate, a pair of first source and drain semiconductor layers provided on the substrate and sandwiching the first channel semiconductor layer, a first gate electrode disposed between the pair of first source and drain semiconductor layers, the first gate electrode and the first channel semiconductor layer sandwiching a first gate insulating film, a second channel semiconductor layer provided over and spaced apart from the first channel semiconductor layer, a pair of second source and drain semiconductor layers provided over the pair of first source and drain semiconductor layers and sandwiching the second channel semiconductor layer, and a second gate electrode disposed between the pair of second source and drain semiconductor layers, the second gate electrode and the second channel semiconductor layer sandwiching a second gate insulating film.

### CROSS-REFERENCE TO RELATED APPLICATION

The present application is based on and claims priority to Japanese patent application No. 2024-088222 filed on May 30, 2024, with Japan Patent Office, the entire contents of which are hereby incorporated by reference.

### BACKGROUND OF THE INVENTION

### 1. Field of the Invention

The disclosures herein relate to semiconductor devices and manufacturing methods of semiconductor devices.

### 2. Description of the Related Art

A CFET (Complementary Field Effect Transistor) made by laminating P-channel transistors and N-channel transistors which are FinFETs (Field Effect Transistors) or nanosheet transistors is known.

The CFET is made by laminating the P-channel transistors and the N-channel transistors whose gate electrodes are electrically connected to each other. Therefore, when a P-channel transistor or an N-channel transistor is used as a single unit, the transistor that is not used is not formed or is not electrically operated. This results in a large chip size.

It is an object of the present disclosure to provide a semiconductor device which can be miniaturized, and its manufacturing method.

### CITATION LIST

### Non Patent Literature

[Non Patent Literature 1] Kevin Zhang, Semiconductor Industry: Present & Future, 2024 IEEE International Solid-State Circuits Conference digest of technical papers, pp. 10-15, (2024).

### SUMMARY OF THE INVENTION

A semiconductor device includes a substrate, and a first transistor including a first channel semiconductor layer of a first conductivity type, provided on the substrate, a pair of first source and drain semiconductor layers of a second conductivity the first conductivity type, type different from provided on the substrate and sandwiching the first channel semiconductor layer, a first gate electrode disposed between the pair of first source and drain semiconductor layers, the first gate electrode and the first channel semiconductor layer sandwiching a first gate insulating a film, second channel semiconductor layer of the first conductivity type, provided over and spaced apart from the first channel semiconductor layer, a pair of second source and drain semiconductor layers of the second conductivity type, provided over the pair of first source and drain semiconductor layers, electrically connected to the pair of first source and drain semiconductor layers, and sandwiching the second channel semiconductor layer, and a second gate electrode disposed between the pair of second source and drain semiconductor layers, and electrically connected to the first gate electrode, the second gate electrode and the second channel semiconductor layer sandwiching a second gate insulating film.

A manufacturing method of a semiconductor device, the semiconductor device including a first transistor including a first channel semiconductor layer of a first conductivity type, provided on a substrate, a pair of first source and drain semiconductor layers of a second conductivity type different from the first conductivity type, provided on the substrate and sandwiching the first channel semiconductor layer, a first gate electrode disposed between the pair of first source and drain semiconductor layers, the first gate electrode and the first channel semiconductor layer sandwiching a first gate insulating film, a second channel semiconductor layer of the first conductivity type, provided over and spaced apart from the first channel semiconductor layer, a pair of second source and drain semiconductor layers of the second conductivity type, provided over the pair of first source and drain semiconductor layers, electrically connected to the pair of first source and drain semiconductor layers, and sandwiching the second channel semiconductor layer, and a second gate electrode disposed between the pair of second source and drain semiconductor layers, and electrically connected to the first gate electrode, the second gate electrode and the second channel semiconductor layer sandwiching a second gate insulating film, a second transistor including a third channel semiconductor layer of the second conductivity type, provided on the substrate, a pair of third source and drain semiconductor layers of the first conductivity type, provided on the substrate and sandwiching the third channel semiconductor layer, and a third gate electrode disposed between the pair of third source and drain semiconductor layers, the third gate electrode and the third channel semiconductor layer sandwiching a third gate insulating film, and a third transistor including a fourth channel semiconductor layer of the first conductivity type, provided over and spaced apart from the third channel semiconductor layer, a pair of fourth source and drain semiconductor layers of the second conductivity type, provided over and spaced apart from the pair of third source and drain semiconductor layers and sandwiching the fourth channel semiconductor layer, and fourth gate electrode disposed between the pair of fourth source and drain semiconductor layers, and electrically connected to the third gate electrode, the fourth gate electrode and the fourth channel semiconductor layer sandwiching a fourth gate insulating film, the method includes forming a first semiconductor layer on the substrate, a second semiconductor layer over and spaced apart from the first semiconductor layer, a third semiconductor layer on the substrate, and a fourth semiconductor layer over and spaced apart from the third semiconductor layer, forming the pair of third source and drain semiconductor layers sandwiching the third semiconductor layer, and simultaneously forming the pair of first source and drain semiconductor layers sandwiching the first semiconductor layer, the pair of second source and drain semiconductor layers sandwiching the second semiconductor layer, and the pair of fourth source and drain semiconductor layers sandwiching the fourth semiconductor layer.

A manufacturing method of a semiconductor device, the semiconductor device including a first transistor including a first channel semiconductor layer of a first conductivity type, provided on a substrate, a pair of first source and drain semiconductor layers of a second conductivity type different from the first conductivity type, provided on the substrate and sandwiching the first channel semiconductor layer, a first gate electrode disposed between the pair of first source and drain semiconductor layers, the first gate electrode and the first channel semiconductor layer sandwiching a first gate insulating film, a second channel semiconductor layer of the first conductivity type, provided over and spaced apart from the first channel semiconductor layer, a pair of second source and drain semiconductor layers of the second conductivity type, provided over the pair of first source and drain semiconductor layers, electrically connected to the pair of first source and drain semiconductor layers, and sandwiching the second channel semiconductor layer, and a second gate electrode disposed between the pair of second source and drain semiconductor layers, and electrically connected to the first gate electrode, the second gate electrode and the second channel semiconductor layer sandwiching a second gate insulating film, a second transistor including a third channel semiconductor layer of the first conductivity type, provided on the substrate, a pair of third source and drain semiconductor layers of the second conductivity type, provided on the substrate and sandwiching the third channel semiconductor layer, a third gate electrode disposed between the pair of third source and drain semiconductor layers, the third gate electrode and the third channel semiconductor layer sandwiching a third gate insulating film, and a third transistor including a fourth channel semiconductor layer of the second conductivity type, provided over and spaced apart from the third channel semiconductor layer, a pair of fourth source and drain semiconductor layers of the first conductivity type, provided over and spaced apart from the pair of third source and drain sandwiching the fourth semiconductor layers and a fourth gate channel semiconductor layer, and electrode disposed between the pair of fourth source and drain semiconductor layers, and electrically connected to the third gate electrode, the fourth gate electrode and the fourth channel semiconductor layer sandwiching a fourth gate insulating film, the method includes forming a first semiconductor layer on the substrate, a second semiconductor layer over and spaced apart from the first semiconductor layer, a third semiconductor layer on the substrate, and a fourth semiconductor layer over and spaced apart from the third semiconductor layer, simultaneously forming the pair of first source and drain semiconductor layers sandwiching the first semiconductor layer, the pair of second source and drain semiconductor layers sandwiching the second semiconductor layer, and the pair of third source and drain semiconductor layers sandwiching the third semiconductor layer, and forming the pair of fourth source and drain semiconductor layers sandwiching the fourth semiconductor layer.

According to the disclosed technology, the semiconductor device can be miniaturized.

### BRIEF DESCRIPTION OF THE DRAWINGS

FIG. 1 is a schematic cross-sectional view illustrating a semiconductor device according to a first embodiment;

FIG. 2 is a perspective view illustrating a second region according to the first embodiment;

FIG. 3A is a cross-sectional view illustrating the second region according to the first embodiment;

FIG. 3B is another cross-sectional view illustrating the second region according to the first embodiment;

FIG. 4A is a cross-sectional view illustrating a first region according to the first embodiment;

FIG. 4B is another cross-sectional view illustrating the first region according to the first embodiment;

FIG. 5A is a cross-sectional view illustrating a third region according to the first embodiment;

FIG. 5B is another cross-sectional view illustrating the third region according to the first embodiment;

FIG. 6A is a cross-sectional view illustrating a third region according to a second comparison;

FIG. 6B is another cross-sectional view illustrating the third region according to the second comparison;

FIG. 7A is a cross-sectional view illustrating the second region in a manufacturing method one of the semiconductor device according to the first embodiment;

FIG. 7B is another cross-sectional view illustrating the second region in the manufacturing method one of the semiconductor device according to the first embodiment;

FIG. 7C is a cross-sectional view illustrating the first region in the manufacturing method one of the semiconductor device according to the first embodiment;

FIG. 7D is another cross-sectional view illustrating the first region in the manufacturing method one of the semiconductor device according to the first embodiment;

FIG. 7E is a cross-sectional view illustrating the third region in the manufacturing method one of the semiconductor device according to the first embodiment;

FIG. 7F is another cross-sectional view illustrating the third region in the manufacturing method one of the semiconductor device according to the first embodiment;

FIG. 8A a cross-sectional view is illustrating the second region in the manufacturing method one of the semiconductor device according to the first embodiment;

FIG. 8B is another cross-sectional view illustrating the second region in the manufacturing method one of the semiconductor device according to the first embodiment;

FIG. 8C is a cross-sectional view illustrating the first region in the manufacturing method one of the semiconductor device according to the first embodiment;

FIG. 8D is another cross-sectional view illustrating the first region in the manufacturing method one of the semiconductor device according to the first embodiment;

FIG. 8E is a cross-sectional view illustrating the third region in the manufacturing method one of the semiconductor device according to the first embodiment;

FIG. 8F is another cross-sectional view illustrating the third region in the manufacturing method one of the semiconductor device according to the first embodiment;

FIG. 9A a is cross-sectional view illustrating the second region in the manufacturing method one of the semiconductor device according to the first embodiment;

FIG. 9B is another cross-sectional view illustrating the second region in the manufacturing method one of the semiconductor device according to the first embodiment;

FIG. 9C is a cross-sectional view illustrating the first region in the manufacturing method one of the semiconductor device according to the first embodiment;

FIG. 9D is another cross-sectional view illustrating the first region in the manufacturing method one of the semiconductor device according to the first embodiment;

FIG. 9E is a cross-sectional view illustrating the third region in the manufacturing method one of the semiconductor device according to the first embodiment;

FIG. 9F is another cross-sectional view illustrating the third region in the manufacturing method one of the semiconductor device according to the first embodiment;

FIG. 10A is a cross-sectional view illustrating the second region in the manufacturing method one of the semiconductor device according to the first embodiment;

FIG. 10B is another cross-sectional view illustrating the second region in the manufacturing method one of the semiconductor device according to the first embodiment;

FIG. 10C is a cross-sectional view illustrating the first region in the manufacturing method one of the semiconductor device according to the first embodiment;

FIG. 10D is another cross-sectional view illustrating the first region in the manufacturing method one of the semiconductor device according to the first embodiment;

FIG. 10E is a cross-sectional view illustrating the third region in the manufacturing method one of the semiconductor device according to the first embodiment;

FIG. 10F is another cross-sectional view illustrating the third region in the manufacturing method one of the semiconductor device according to the first embodiment;

FIG. 11A is a cross-sectional view illustrating the second region in the manufacturing method one of the semiconductor device according to the first embodiment;

FIG. 11B is another cross-sectional view illustrating the second region in the manufacturing method one of the semiconductor device according to the first embodiment;

FIG. 11C is a cross-sectional view illustrating the first region in the manufacturing method one of the semiconductor device according to the first embodiment;

FIG. 11D is another cross-sectional view illustrating the first region in the manufacturing method one of the semiconductor device according to the first embodiment;

FIG. 11E is a cross-sectional view illustrating the third region in the manufacturing method one of the semiconductor device according to the first embodiment;

FIG. 11F is another cross-sectional view illustrating the third region in the manufacturing method one of the semiconductor device according to the first embodiment;

FIG. 12A a is cross-sectional view illustrating the second region in the manufacturing method one of the semiconductor device according to the first embodiment;

FIG. 12B is another cross-sectional view illustrating the second region in the manufacturing method one of the semiconductor device according to the first embodiment;

FIG. 12C is a cross-sectional view illustrating the first region in the manufacturing method one of the semiconductor device according to the first embodiment;

FIG. 12D is another cross-sectional view illustrating the first region in the manufacturing method one of the semiconductor device according to the first embodiment;

FIG. 12E is a cross-sectional view illustrating the third region in the manufacturing method one of the semiconductor device according to the first embodiment;

FIG. 12F is another cross-sectional view illustrating the third region in the manufacturing method one of the semiconductor device according to the first embodiment;

FIG. 13A is a cross-sectional view illustrating the second region in the manufacturing method one of the semiconductor device according to the first embodiment;

FIG. 13B is another cross-sectional view illustrating the second region in the manufacturing method one of the semiconductor device according to the first embodiment;

FIG. 13C is a cross-sectional view illustrating the first region in the manufacturing method one of the semiconductor device according to the first embodiment;

FIG. 13D is another cross-sectional view illustrating the first region in the manufacturing method one of the semiconductor device according to the first embodiment;

FIG. 13E is a cross-sectional view illustrating the third region in the manufacturing method one of the semiconductor device according to the first embodiment;

FIG. 13F is another cross-sectional view illustrating the third region in the manufacturing method one of the semiconductor device according to the first embodiment;

FIG. 14A is a cross-sectional view illustrating the second region in the manufacturing method one of the semiconductor device according to the first embodiment;

FIG. 14B is another cross-sectional view illustrating the second region in the manufacturing method one of the semiconductor device according to the first embodiment;

FIG. 14C is a cross-sectional view illustrating the first region in the manufacturing method one of the semiconductor device according to the first embodiment;

FIG. 14D is another cross-sectional view illustrating the first region in the manufacturing method one of the semiconductor device according to the first embodiment;

FIG. 14E is a cross-sectional view illustrating the third region in the manufacturing method one of the semiconductor device according to the first embodiment;

FIG. 14F is another cross-sectional view illustrating the third region in the manufacturing method one of the semiconductor device according to the first embodiment;

FIG. 15A is a cross-sectional view illustrating the second region in the manufacturing method one of the semiconductor device according to the first embodiment;

FIG. 15B is another cross-sectional view illustrating the second region in the manufacturing method one of the semiconductor device according to the first embodiment;

FIG. 15C is a cross-sectional view illustrating the first region in the manufacturing method one of the semiconductor device according to the first embodiment;

FIG. 15D is another cross-sectional view illustrating the first region in the manufacturing method one of the semiconductor device according to the first embodiment;

FIG. 15E is a cross-sectional view illustrating the third region in the manufacturing method one of the semiconductor device according to the first embodiment;

FIG. 15F is another cross-sectional view illustrating the third region in the manufacturing method one of the semiconductor device according to the first embodiment;

FIG. 16A is a cross-sectional view illustrating the second region in the manufacturing method one of the semiconductor device according to the first embodiment;

FIG. 16B is another cross-sectional view illustrating the second region in the manufacturing method one of the semiconductor device according to the first embodiment;

FIG. 16C is a cross-sectional view illustrating the first region in the manufacturing method one of the semiconductor device according to the first embodiment;

FIG. 16D is another cross-sectional view illustrating the first region in the manufacturing method one of the semiconductor device according to the first embodiment;

FIG. 16E is a cross-sectional view illustrating the third region in the manufacturing method one of the semiconductor device according to the first embodiment;

FIG. 16F is another cross-sectional view illustrating the third region in the manufacturing method one of the semiconductor device according to the first embodiment;

FIG. 17A is a cross-sectional view illustrating the second region in the manufacturing method one of the semiconductor device according to the first embodiment;

FIG. 17B is another cross-sectional view illustrating the second region in the manufacturing method one of the semiconductor device according to the first embodiment;

FIG. 17C is a cross-sectional view illustrating the first region in the manufacturing method one of the semiconductor device according to the first embodiment;

FIG. 17D is another cross-sectional view illustrating the first region in the manufacturing method one of the semiconductor device according to the first embodiment;

FIG. 17E is a cross-sectional view illustrating the third region in the manufacturing method one of the semiconductor device according to the first embodiment;

FIG. 17F is another cross-sectional view illustrating the third region in the manufacturing method one of the semiconductor device according to the first embodiment;

FIG. 18A is a cross-sectional view illustrating the second region in the manufacturing method one of the semiconductor device according to the first embodiment;

FIG. 18B is another cross-sectional view illustrating the second region in the manufacturing method one of the semiconductor device according to the first embodiment;

FIG. 18C is a cross-sectional view illustrating the first region in the manufacturing method one of the semiconductor device according to the first embodiment;

FIG. 18D is another cross-sectional view illustrating the first region in the manufacturing method one of the semiconductor device according to the first embodiment;

FIG. 18E is a cross-sectional view illustrating the third region in the manufacturing method one of the semiconductor device according to the first embodiment;

FIG. 18F is another cross-sectional view illustrating the third region in the manufacturing method one of the semiconductor device according to the first embodiment;

FIG. 19A is a cross-sectional view illustrating the second region in the manufacturing method one of the semiconductor device according to the first embodiment;

FIG. 19B is another cross-sectional view illustrating the second region in the manufacturing method one of the semiconductor device according to the first embodiment;

FIG. 19C is a cross-sectional view illustrating the first region in the manufacturing method one of the semiconductor device according to the first embodiment;

FIG. 19D is another cross-sectional view illustrating the first region in the manufacturing method one of the semiconductor device according to the first embodiment;

FIG. 19E is a cross-sectional view illustrating the third region in the manufacturing method one of the semiconductor device according to the first embodiment;

FIG. 19F is another cross-sectional view illustrating the third region in the manufacturing method one of the semiconductor device according to the first embodiment;

FIG. 20A is a cross-sectional view illustrating the second region in the manufacturing method one of the semiconductor device according to the first embodiment;

FIG. 20B is another cross-sectional view illustrating the second region in the manufacturing method one of the semiconductor device according to the first embodiment;

FIG. 20C is a cross-sectional view illustrating the first region in the manufacturing method one of the semiconductor device according to the first embodiment;

FIG. 20D is another cross-sectional view illustrating the first region in the manufacturing method one of the semiconductor device according to the first embodiment;

FIG. 20E is a cross-sectional view illustrating the third region in the manufacturing method one of the semiconductor device according to the first embodiment;

FIG. 20F is another cross-sectional view illustrating the third region in the manufacturing method one of the semiconductor device according to the first embodiment;

FIG. 21A is a cross-sectional view illustrating the second region in the manufacturing method one of the semiconductor device according to the first embodiment;

FIG. 21B is another cross-sectional view illustrating the second region in the manufacturing method one of the semiconductor device according to the first embodiment;

FIG. 21C is a cross-sectional view illustrating the first region in the manufacturing method one of the semiconductor device according to the first embodiment;

FIG. 21D is another cross-sectional view illustrating the first region in the manufacturing method one of the semiconductor device according to the first embodiment;

FIG. 21E is a cross-sectional view illustrating the third region in the manufacturing method one of the semiconductor device according to the first embodiment;

FIG. 21F is another cross-sectional view illustrating the third region in the manufacturing method one of the semiconductor device according to the first embodiment;

FIG. 22A is a cross-sectional view illustrating the second region in the manufacturing method one of the semiconductor device according to the first embodiment;

FIG. 22B is another cross-sectional view illustrating the second region in the manufacturing method one of the semiconductor device according to the first embodiment;

FIG. 22C is a cross-sectional view illustrating the first region in the manufacturing method one of the semiconductor device according to the first embodiment;

FIG. 22D is another cross-sectional view illustrating the first region in the manufacturing method one of the semiconductor device according to the first embodiment;

FIG. 22E is a cross-sectional view illustrating the third region in the manufacturing method one of the semiconductor device according to the first embodiment;

FIG. 22F is another cross-sectional view illustrating the third region in the manufacturing method one of the semiconductor device according to the first embodiment;

FIG. 23A a cross-sectional view is illustrating the second region in the manufacturing method one of the semiconductor device according to the first embodiment;

FIG. 23B is another cross-sectional view illustrating the second region in the manufacturing method one of the semiconductor device according to the first embodiment;

FIG. 23C is a cross-sectional view illustrating the first region in the manufacturing method one of the semiconductor device according to the first embodiment;

FIG. 23D is another cross-sectional view illustrating the first region in the manufacturing method one of the semiconductor device according to the first embodiment;

FIG. 23E is a cross-sectional view illustrating the third region in the manufacturing method one of the semiconductor device according to the first embodiment;

FIG. 23F is another cross-sectional view illustrating the third region in the manufacturing method one of the semiconductor device according to the first embodiment;

FIG. 24A is cross-sectional view illustrating the second region in a manufacturing method two of the semiconductor device according to the first embodiment;

FIG. 24B is another cross-sectional view illustrating the second region in the manufacturing method two of the semiconductor device according to the first embodiment;

FIG. 24C is a cross-sectional view illustrating the first region in the manufacturing method two of the semiconductor device according to the first embodiment;

FIG. 24D is another cross-sectional view illustrating the first region in the manufacturing method two of the semiconductor device according to the first embodiment;

FIG. 24E is a cross-sectional view illustrating the third region in the manufacturing method two of the semiconductor device according to the first embodiment;

FIG. 24F is another cross-sectional view illustrating the third region in the manufacturing method two of the semiconductor device according to the first embodiment;

FIG. 25A is a cross-sectional view illustrating the second region in the manufacturing method two of the semiconductor device according to the first embodiment;

FIG. 25B is another cross-sectional view illustrating the second region in the manufacturing method two of the semiconductor device according to the first embodiment;

FIG. 25C is a cross-sectional view illustrating the first region in the manufacturing method two of the semiconductor device according to the first embodiment;

FIG. 25D is another cross-sectional view illustrating the first region in the manufacturing method two of the semiconductor device according to the first embodiment;

FIG. 25E is a cross-sectional view illustrating the third region in the manufacturing method two of the semiconductor device according to the first embodiment;

FIG. 25F is another cross-sectional view illustrating the third region in the manufacturing method two of the semiconductor device according to the first embodiment;

FIG. 26A is a cross-sectional view illustrating a second region according to a first modification of the first embodiment;

FIG. 26B is a cross-sectional view illustrating the second region according to the first modification of the first embodiment;

FIG. 27A is a cross-sectional view illustrating a first region according to the first modification of the first embodiment;

FIG. 27B is a cross-sectional view illustrating the first region according to the first modification of the first embodiment;

FIG. 28A is a cross-sectional view illustrating a third region according to the first modification of the first embodiment;

FIG. 28B is a cross-sectional view illustrating the third region according to the first modification of the first embodiment;

FIG. 29A is a cross-sectional view illustrating a second region according to a second modification of the first embodiment;

FIG. 29B is a cross-sectional view illustrating the second region according to the second modification of the first embodiment;

FIG. 30A is a cross-sectional view illustrating a first region according to the second modification of the first embodiment;

FIG. 30B is a cross-sectional view illustrating the first region according to the second modification of the first embodiment;

FIG. 31A is a cross-sectional view illustrating a third region according to the second modification of the first embodiment;

FIG. 31B is a cross-sectional view illustrating the third region according to the second modification of the first embodiment;

FIG. 32A is a cross-sectional view illustrating a first region according to a third modification of the first embodiment;

FIG. 32B is a cross-sectional view illustrating the first region according to the third modification of the first embodiment;

FIG. 33A is a cross-sectional view illustrating a third region according to the third modification of the first embodiment;

FIG. 33B is a cross-sectional view illustrating the third region according to the third modification of the first embodiment;

FIG. 34A is a cross-sectional view illustrating a first region according to the fourth modification of the first embodiment;

FIG. 34B is a cross-sectional view illustrating the first region according to the fourth modification of the first embodiment;

FIG. 35A is a cross-sectional view illustrating a third region according to the fourth modification of the first embodiment;

FIG. 35B is a cross-sectional view illustrating the third region according to the fourth modification of the first embodiment;

FIG. 36A is a cross-sectional view illustrating a second region of the semiconductor device according to a fifth modification of the first embodiment;

FIG. 36B is another cross-sectional view illustrating the second region of the semiconductor device according to a fifth modification of the first embodiment;

FIG. 36C is a cross-sectional view illustrating a first region of the semiconductor device according to a fifth modification of the first embodiment;

FIG. 36D is another cross-sectional view illustrating the first region of the semiconductor device according to a fifth modification of the first embodiment;

FIG. 36E is a cross-sectional view illustrating the third region of the semiconductor device according to a fifth modification of the first embodiment;

FIG. 36F is another cross-sectional view illustrating the third region of the semiconductor device according to a fifth modification of the first embodiment;

FIG. 37 is a circuit diagram of a semiconductor device according to a second embodiment;

FIG. 38 is a circuit diagram of the semiconductor device according to the second embodiment;

FIG. 39 is a circuit diagram of a semiconductor device according to a first modification of the second embodiment; and

FIG. 40 is a circuit diagram of the semiconductor device according to the second modification of the second embodiment.

### DESCRIPTION OF THE PREFERRED EMBODIMENTS

In the following, embodiments of the present invention will be described with reference to the accompanying drawings. The following embodiments are examples for embodying the technical concept of the invention, and the present disclosure is not limited to the structure and numerical values described in the present document. In the drawings, the same constituent elements are denoted with the same reference numerals, and redundant description related to them may be omitted. In each of the drawings, sizes and shapes may be partially exaggerated so that the contents of the invention can be easily understood.

### First Embodiment

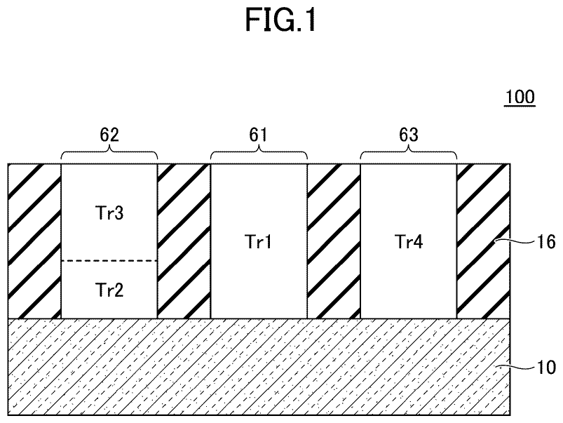

FIG. 1 is a schematic cross-sectional view illustrating a semiconductor device according to a first embodiment. As shown in FIG. 1, the semiconductor device 100 according to the first embodiment includes a substrate 10, an insulating film 16, a first region 61, a second region 62, and a third region 63. The first region 61 is provided on the substrate 10 and includes a transistor Tr1. The second region 62 is provided on the substrate 10 and includes transistors Tr2 and Tr3. The third region 63 is provided on the substrate 10 and includes a transistor Tr4. The transistors Tr1 and Tr3 are, for example, N-channel transistors. The transistors Tr2 and Tr4 are, for example, P-channel transistors. The insulating film 16 is provided on the substrate 10 and surrounds the first region 61, the second region 62, and the third region 63. Driving capability of the transistor Tr1 is approximately twice that of the transistor Tr3, driving of the and capability transistor Tr4 is approximately twice that of the transistor Tr2.

A conductivity type of channel semiconductor layers 21A to 21E is determined not only by impurity elements doped in the channel semiconductor layers 21A to 21E, but also by a combination of work functions of the channel semiconductor layers 21A to 21E and gate electrodes 25A to 25E. Even if the channel semiconductor layers 21A to 21E are, for example, intrinsic semiconductors, they can behave as N-types, in which electrons conduct as carriers or P-types, in which holes conduct as carriers. In the following description, an expression “N-type channel semiconductor layer” is used when electrons conduct as carriers, and “P-type channel semiconductor layer” when holes conduct as carriers.

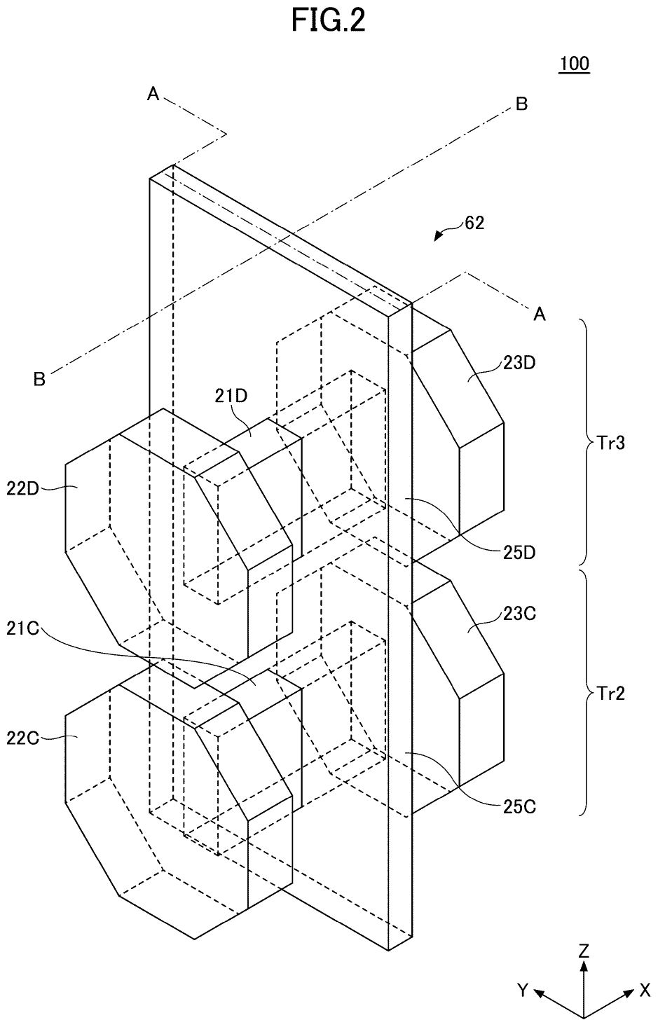

FIG. 2 is a perspective view illustrating the second region according to the first embodiment. FIGS. 3A and 3B are cross-sectional views illustrating the second region according to the first embodiment. In FIG. 2, the channel semiconductor layers 21C and 21D, source and drain semiconductor layers 22C, 22D, 23C and 23D, and the gate electrodes 25C and 25D are shown. FIGS. 3A and 3B correspond to cross-sectional views A-A and B-B in FIG. 2, respectively. A thickness direction of the substrate 10 is referred as a Z-direction, an arrangement direction of the source and drain semiconductor layers 22C and 23C is referred as an X-direction, and a direction orthogonal to the Z-direction and the X-direction is referred as a Y-direction.

As shown in FIGS. 2 to 3B, the second region 62 of the semiconductor device 100 has transistors Tr2 and Tr3. An element isolation insulating film 12 is provided on an upper layer of the substrate 10. The transistor Tr2 (second transistor) has a channel semiconductor layer 21C (third channel semiconductor layer), a pair of source and drain semiconductor layers 22C and 23C (a pair of third source and drain semiconductor layers), a gate insulating film 24C (third gate insulating film), and a gate electrode 25C (third gate electrode).

The channel semiconductor layer 21C is provided on the substrate 10 surrounded by the element isolation insulating film 12, and has a third conductivity type (e.g., N-type). The pair of source and drain semiconductor layers 22C and 23C are provided on the substrate 10, sandwich the channel semiconductor layer 21C, and have a fourth conductivity type (e.g., P-type) different from the third conductivity type. The gate electrode 25C and the channel semiconductor layer 21C sandwich the gate insulating film 24C, between the source and drain semiconductor layers 22C and 23C.

The transistor Tr3 (third transistor) has a channel semiconductor layer 21D (fourth channel semiconductor layer), a pair of source and drain semiconductor layers 22D and 23D (pair of fourth source and drain semiconductor layers), a gate insulating film 24D (fourth gate insulating film), and a gate electrode 25D (fourth gate electrode). The channel semiconductor layer 21D is provided over the channel semiconductor layer 21C and spaced apart from the channel semiconductor layer 21C, and has the fourth conductivity type (e.g., P-type). A pair of source and drain semiconductor layers 22D and 23D are provided over the source and drain semiconductor layers 22C and 23C spaced apart from the source and drain semiconductor layers 22C and 23C, sandwich the channel semiconductor layer 21D, and have the third conductivity type (e.g., N-type). The gate electrode 25D and the channel semiconductor layer 21D sandwich the gate insulating film 24D between the source and drain semiconductor layers 22D and 23D. The gate electrodes 25C and 25D are integrally provided and electrically connected. The insulating film 14 electrically separates the channel semiconductor layers 21C and 21D, and electrically separates the pair of source and drain semiconductor layers 22C and 23C from the pair of source and drain semiconductor layers 22D and 23D, respectively. In the transistors Tr2 and Tr3, a spacer 26 is provided so as to sandwich the gate electrodes 25C and 25D in the X-direction.

In the second region 62, a fourth conductive channel transistor Tr3 is provided on the third conductive channel transistor Tr2. The transistor Tr2 and the transistor Tr3 are CFET structures having gate electrodes 25C and 25D having the same potential, and a CMOS inverter can be formed, for example.

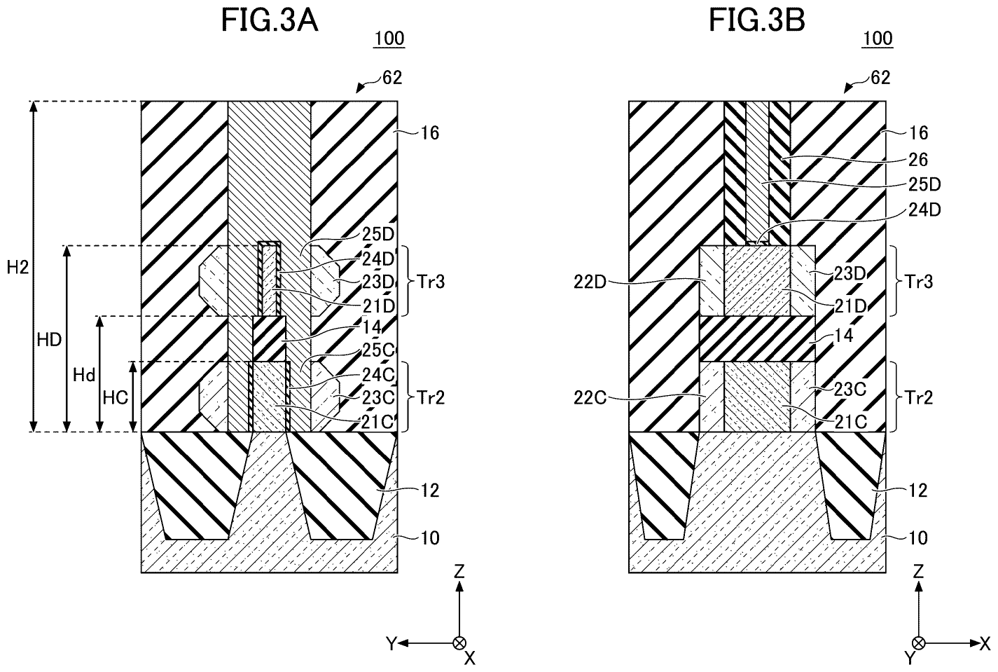

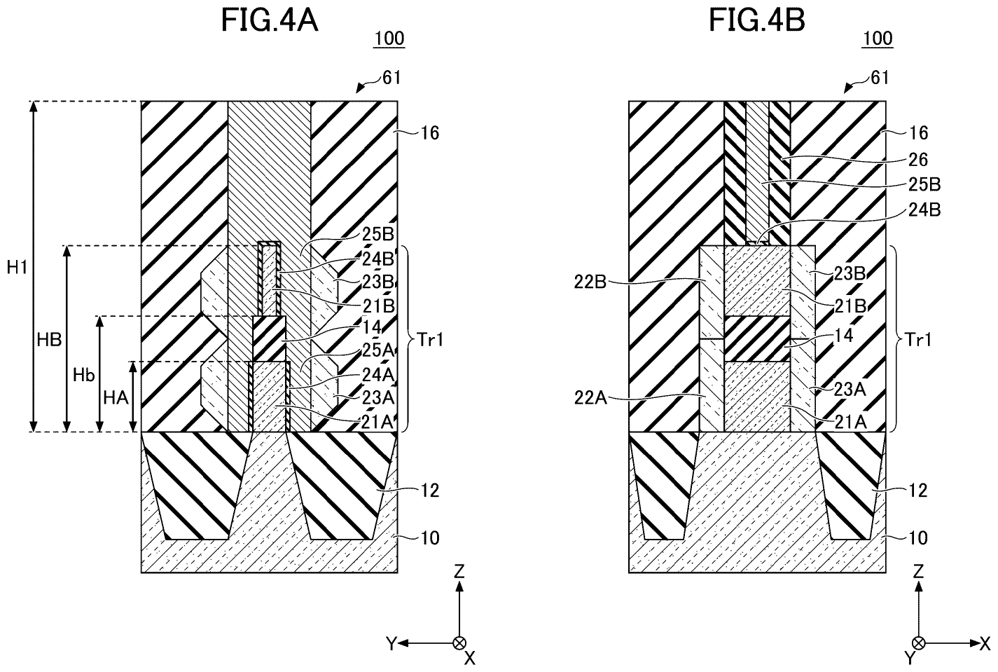

FIGS. 4A and 4B are cross-sectional views illustrating the first region according to the first embodiment. As shown in FIGS. 4A and 4B, the first region 61 of the semiconductor device 100 has a transistor Tr1. The transistor Tr1 (first transistor) has a channel semiconductor layer 21A (first channel semiconductor layer), a pair of source and drain semiconductor layers 22A and 23A (pair of first source and drain semiconductor layers), a gate insulating film 24A (first gate insulating film) and a gate electrode 25A (first gate electrode), a channel semiconductor layer 21B (second channel semiconductor layer), a pair of source and drain semiconductor layers 22B and 23B (pair of second source and drain semiconductor layers), and a gate insulating film 24B (second gate insulating film) and a gate electrode 25B (second gate electrode).

The channel semiconductor layer 21A is provided on the substrate 10 surrounded by the element isolation insulating film 12 and has a first conductivity type (e.g., P-type). A pair of source and drain semiconductor layers 22A and 23A are provided on the substrate 10, sandwich the channel semiconductor layer 21A, and have a second conductivity type (e.g., N-type) different from the first conductivity type. The gate electrode 25A and the channel semiconductor layer 21A sandwich the gate insulating film 24A between the pair of source and drain semiconductor layers 22A and 23A.

The channel semiconductor layer 21B (second channel semiconductor layer) is provided over the channel semiconductor layer 21A and spaced apart from the channel semiconductor layer 21A, and has the first conductivity type (e.g., P-type). A pair of source and drain semiconductor layers 22B and 23B are provided over the source and drain semiconductor layers 22A and 23A, are electrically connected to the source and drain semiconductor layers 22A and 23A, sandwich the channel semiconductor layer 21B, and have the second conductivity type (e.g., N-type). The gate electrode 25B and the channel semiconductor layer 21B sandwich the gate insulating film 24B between the source and drain semiconductor layers 22B and 23B, and is electrically connected to the gate electrode 25A. The insulating film 14 is provided between the channel semiconductor layers 21A and 21B.

In the transistor Tr1, the source and drain semiconductor layers 22A and 22B are electrically connected, the source and drain semiconductor layers 23A and 23B are electrically connected, and the gate electrodes 25A and 25B are electrically connected. Thus, the transistor Tr1 functions as one transistor in which the two channel semiconductor layers 21A and 21B are provided in parallel. The driving capability of the transistor Tr1 is approximately twice that of the transistor Tr3.

FIGS. 5A and 5B are cross-sectional views illustrating a third region according to the first embodiment. As shown in FIGS. 5A and 5B, the third region 63 of the semiconductor device 100 has a transistor Tr4. The transistor Tr4 (fourth transistor) has a channel semiconductor layer 21E (fifth channel semiconductor layer), a pair of source and drain semiconductor layers 22E and 23E (a pair of fifth source and drain semiconductor layers), a gate insulating film 24E (fifth gate insulating film) and a gate electrode 25E (fifth gate electrode), a channel semiconductor layer 21F (sixth channel semiconductor layer), a pair of source and drain semiconductor layers 22F and 23F (a pair of sixth source and drain semiconductor layers), and a gate insulating film 24F (sixth gate insulating film) and a gate electrode 25F (sixth gate electrode).

The channel semiconductor layer 21E is provided on the substrate 10 surrounded by the element isolation insulating film 12 and has the second conductivity type (e.g., N-type). A pair of source and drain semiconductor layers 22E and 23E are provided on the substrate 10, sandwich the channel semiconductor layer 21E, and have the first conductivity type (e.g., P-type). The gate electrode 25E and the channel semiconductor layer 21E sandwich the gate insulating film 24E between the pair of source and drain semiconductor layers 22E and 23E.

The channel semiconductor layer 21F (the sixth channel semiconductor layer) is provided over the channel semiconductor layer 21E, spaced apart from the channel semiconductor layer 21E, and has the second conductivity type (e.g., N-type). A pair of source and drain semiconductor layers 22F and 23F are provided over the source and drain semiconductor layers 22E and 23E, electrically connected to the source and drain semiconductor layers 22E and 23E, respectively, sandwich the channel semiconductor layer 21F, and have the second conductivity type (e.g., P-type). The gate electrode 25F and the channel semiconductor layer 21F sandwich the gate insulating film 24F between the source and drain semiconductor layers 22F and 23F, and is electrically connected to the gate electrode 25E. The insulating film 14 is provided between the channel semiconductor layers 21E and 21F.

In the transistor Tr4, the source and drain semiconductor layers 22E and 22F are electrically connected, the source and drain semiconductor layers 23E and 23F are electrically connected, and the gate electrodes 25E and 25F are electrically connected. Thus, transistor Tr4 functions as one transistor in which two channel semiconductor layers 21E and 21F are provided in parallel. The driving capability of the transistor Tr4 is approximately twice that of the transistor Tr2.

The substrate 10 is a semiconductor substrate such as, for example, a silicon (Si) substrate. The channel semiconductor layers 21A to 21F, the source and drain semiconductor layers 22A to 22F, and 23A to 23F are, for example, single crystals and are, for example, silicon layers or silicon germanium (SiGe) layers. P-type source and drain semiconductor layers 22A to 22F, 23A to 23F, and N-type channel semiconductor layers 21A to 21F are preferably silicon germanium layers. Thus, hole mobility in the N-type channel semiconductor layers 21A to 21F can be improved. The N-type semiconductor layer is doped with, for example, phosphorus (P) or arsenic (As). The P-type semiconductor layer is doped with, for example, boron (B) or aluminum (Al). As described above, the channel semiconductor layers 21A to 21E may be intrinsic semiconductors that are not doped with impurity elements even if they have the N-type or the P-type. The gate insulating films 24A to 24F are, for example, a silicon oxide film or a high-k film (a film having a higher relative dielectric constant than silicon oxide) such as a hafnium oxide film. The gate electrodes 25A to 25F are, for example, a polycrystalline silicon layer or a metal layer. A metal film for adjusting the work function may be provided between the gate electrodes 25A to 25F and the gate insulating films 24A to 24F. The insulating film 14 is, for example, a silicon nitride film or a silicon oxide film. The insulating film 16 is, for example, a silicon oxide film.

### First Comparison

In a first comparison, when the P- or N-channel transistor is used as a single unit, only the transistors Tr2 and Tr3 shown in FIGS. 3A and 3B are used. In this case, since the gate electrodes 25C and 25D are electrically connected, the gate parasitic capacitance becomes large.

### Second Comparison

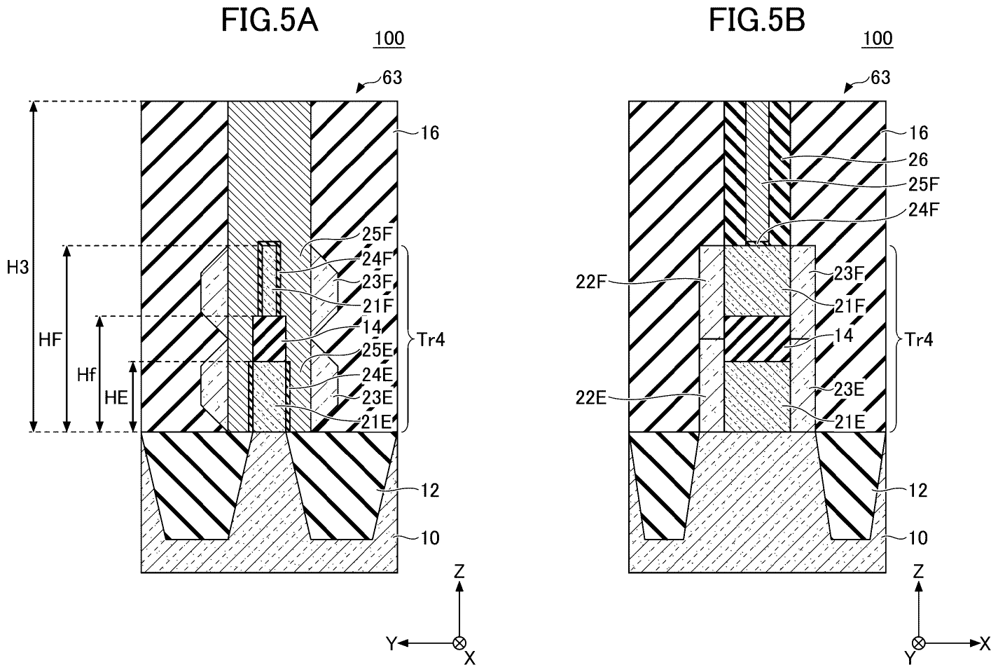

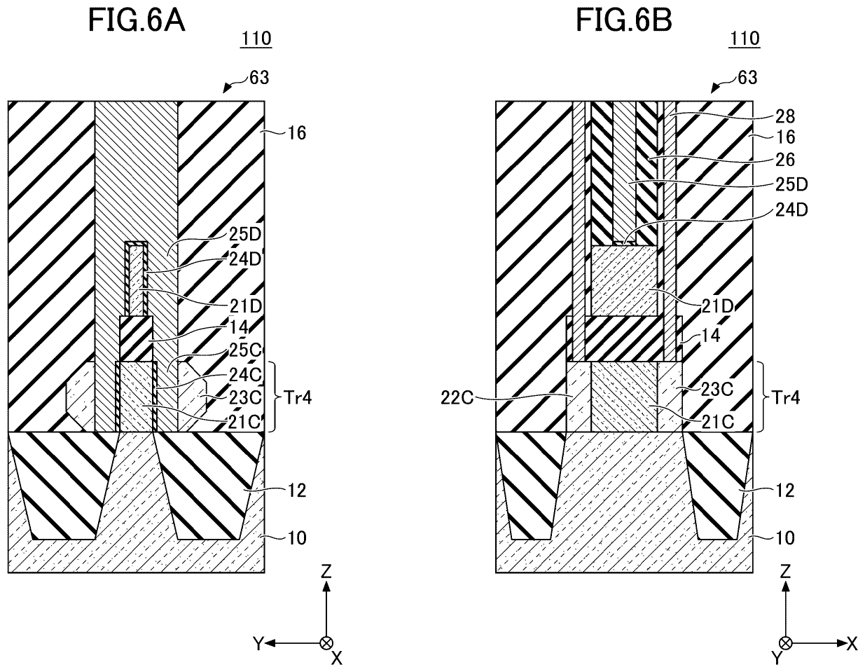

FIGS. 6A and 6B are cross-sectional views illustrating a third region according to a second comparison. As shown in FIGS. 6A and 6B, in a semiconductor device 110 of the second comparison, as the transistor Tr4, a transistor having the same structure as the transistor Tr2 in FIGS. 3A and 3B in the first embodiment is provided. The source and drain semiconductor layers 22D and 23D are not provided on the transistor Tr4. Other structures are the same as those in FIGS. 3A and 3B in the first embodiment. A contact 28 is provided which penetrates the insulating film 16 and connects to the source and drain semiconductor layers 22C and 23C. The contact 28 is formed from the upper surface of the insulating film 16 to the upper surfaces of the source and drain semiconductor layers 22C and 23C. Therefore, an aspect ratio of the contact 28 increases, and forming the contact 28 becomes difficult. As a result, the contact resistance between the contact 28 and the source and drain semiconductor layers 22C and 23C increases, leading to the degradation of its characteristics. Alternatively, the diameter of the contact 28 increases, and the size of the contact 28 becomes larger.

When the transistors Tr1 and Tr4 are used as a single unit instead of the CFET, a larger driving capability may be required compared to Tr2 and Tr3 used in the CFET. In such a case, in the first and second comparisons, a plurality of transistors Tr1 or Tr4 are arranged in an XY plane. Therefore, the chip size becomes larger and the semiconductor device becomes larger.

### Description of the First Embodiment

In the first embodiment, as shown in FIGS. 4A to 5B, the transistors Tr1 and have channel Tr4 semiconductor layers 21A and 21B in parallel. Therefore, the driving capability can be approximately twice as large as in the first and second comparisons with the same chip area. As a result, the chip area required to form a transistor with the same driving capability can be reduced to approximately half. Therefore, the size can be reduced. The gate electrodes 25A and 25B face the channel semiconductor layers 21A and 21B, and the gate electrodes 25E and 25F face the channel semiconductor layers 21E and 21F. Thus, the transistor characteristics can be improved without increasing parasitic capacitance as in the first embodiment. Furthermore, the aspect ratio of the contact can be reduced.

### Manufacturing Method One of the First Embodiment

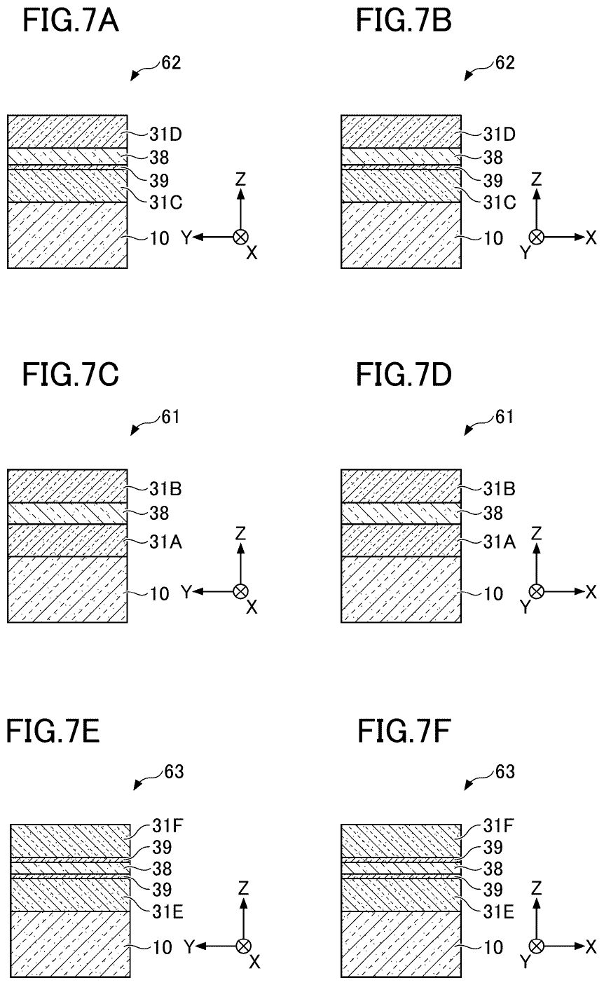

FIGS. 7A to 23F are cross-sectional views illustrating a manufacturing method one of the semiconductor device according to the first embodiment. FIGS. 7A to 23A and 7B to 23B are cross-sectional views of the second region 62. FIGS. 7C to 23C and 7D to 23D are cross-sectional views of the first region 61, and FIGS. 7E to 23E and 7F to 23F are cross-sectional views of the third region 63.

As shown in FIGS. 7A to 7F, in the second region 62, a semiconductor layer 31C, a barrier layer 39, a dummy layer 38, and a semiconductor layer 31D are sequentially laminated on the substrate 10. In the first region 61, a semiconductor layer 31A, a dummy layer 38, and a semiconductor layer 31B are laminated in this order. In the third region 63, a semiconductor layer 31E, a barrier layer 39, a dummy layer 38, a barrier layer 39, and a semiconductor layer 31F are laminated in this order.

An example will be described in which the semiconductor layers 31A, 31B, and 31D are silicon layers and the semiconductor layers 31C, 31E, and 31F are silicon germanium layers. First, a silicon layer is epitaxially grown on the substrate 10. Then, the silicon layers of the second region 62 and the third region 63 are removed. A silicon germanium layer is formed on the substrate 10 of the second region 62 and the third region 63 by protecting the lateral surfaces of the removed portions. A barrier layer 39 of a silicon layer is formed on the silicon layer and the silicon germanium layer. As a result, a semiconductor layer 31C of a silicon germanium layer is formed in the second region 62, a semiconductor layer 31A of a silicon layer is formed in the first region 61, and a semiconductor layer 31E of a silicon germanium layer is formed in the third region 63.

A dummy layer 38 having a high germanium concentration is formed on the barrier layer 39. A silicon layer is formed on the dummy layer 38. Then, the silicon layer of the third region 63 is removed. A barrier layer 39 of a silicon layer and a silicon germanium layer are formed on the substrate 10 of the third region 63 by protecting the lateral surface of the removed portion. As described above, a semiconductor layer 31D of a silicon layer is formed in the second region 62, a semiconductor layer 31B of a silicon layer is formed in the first region 61, and a semiconductor layer 31F of a silicon germanium layer is formed in the third region 63. The thickness of the semiconductor layers 31A to 31F is, for example, 20 nm to 30 nm, the thickness of the dummy layer 38 is, for example, 30 nm, and the thickness of the barrier layer 39 is, for example, several nanometers. The silicon layer and the silicon germanium layer described above are examples. A semiconductor layer of any material can be used as each semiconductor layer. The thickness of the semiconductor layers 31A to 31F can be, for example, 4 nm to 50 nm, and the thickness of the dummy layer 38 can be, for example, 4 nm to 50 nm.

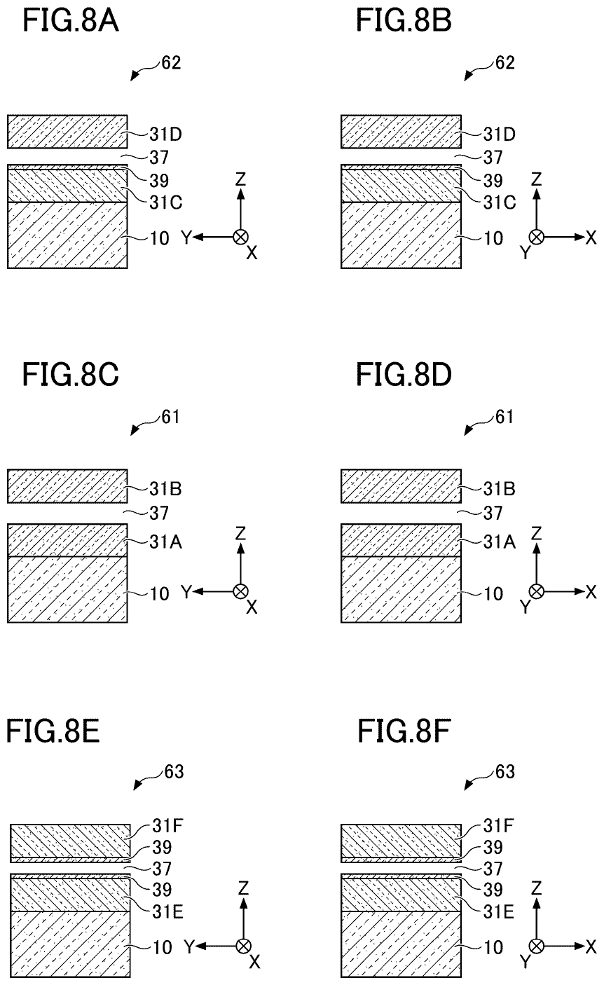

As shown in FIGS. 8A to 8F, a gap 37 is formed by etching the dummy layer 38 having a high germanium composition. By providing the barrier layer 39, etching of the semiconductor layers 31 C, 31E, and 31F can be suppressed when etching the dummy layer 38. The dummy layer 38 may be made of a material having etching selectivity with the semiconductor layers 31A to 31F and capable of epitaxial growth.

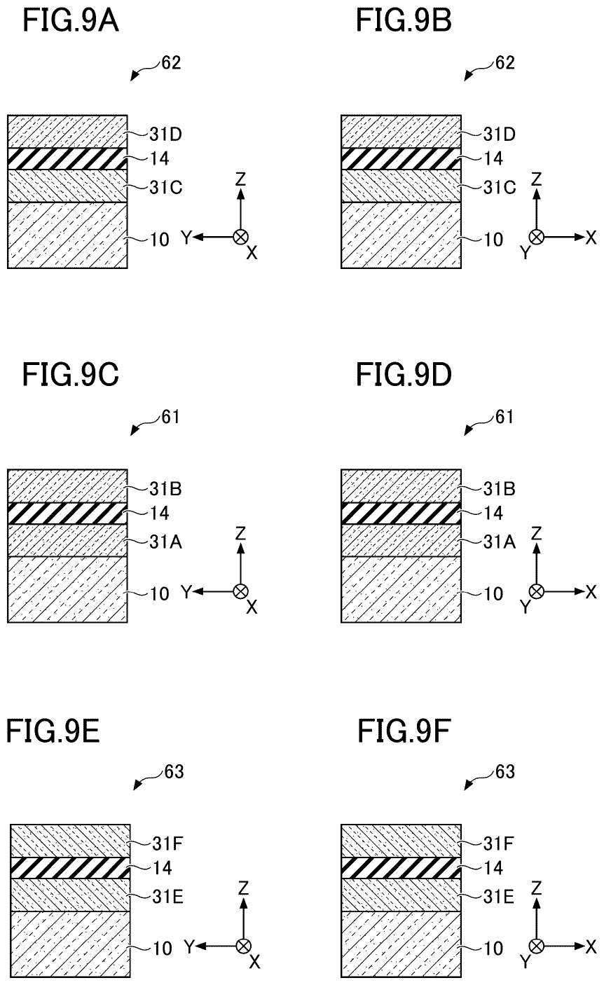

As shown in FIGS. 9A to 9F, an insulating film 14 is formed in the gap 37 using, for example, an ALD (Atomic Layer Deposition) method. Illustration of the barrier layer 39 will be omitted hereinafter.

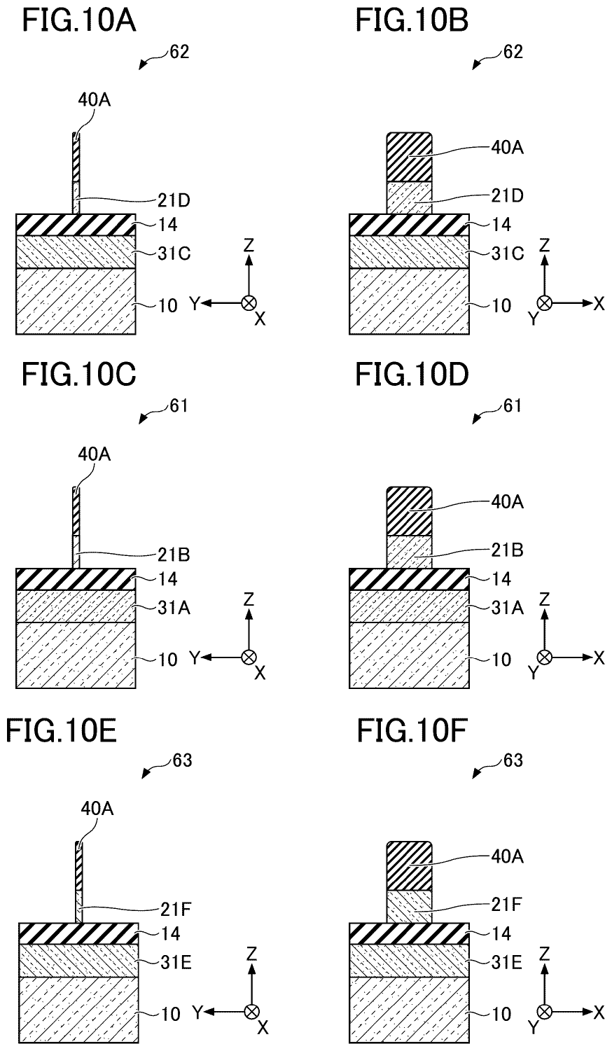

As shown in FIGS. 10A to 10F, a mask layer 40A is formed on the semiconductor layers 31B, 31D and 31F. The mask layer 40A is an insulating film such as a silicon nitride film. The mask layer 40A is processed to a desired shape by using a photolithography method and an etching method. Using the mask layer 40A as a mask, semiconductor layers 31B, 31D and 31F are processed by, for example, etching. Thus, channel semiconductor layers 21B, 21D, and 21F are formed from semiconductor layers 31B, 31D, and 31F, respectively. The widths of the channel semiconductor layers 21B, 21D and 21F in the Y-direction are, for example, 6 nm. The channel semiconductor layers 21B, 21D, and 21F have a fin structure. The width of the channel semiconductor layers 21B, 21D and 21F in the Y-direction can be, for example, 4 nm to 15 nm.

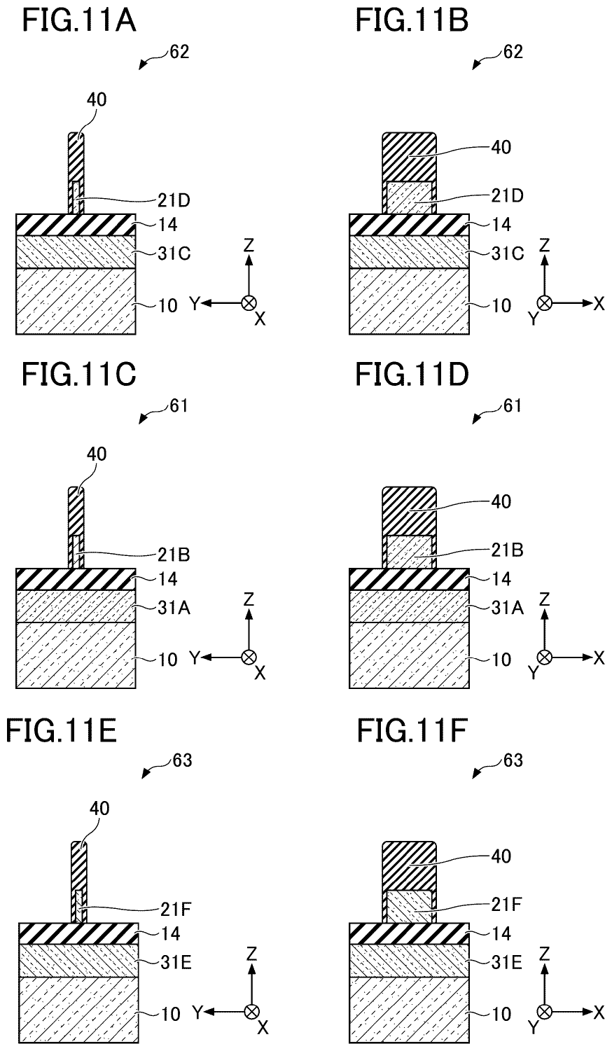

As shown in FIGS. 11A to 11F, a mask layer 40 including a mask layer 40A is formed by forming an insulating film as a lateral wall on the lateral surfaces of the mask layer 40A and the channel semiconductor layers 21B, 21D, and 21F.

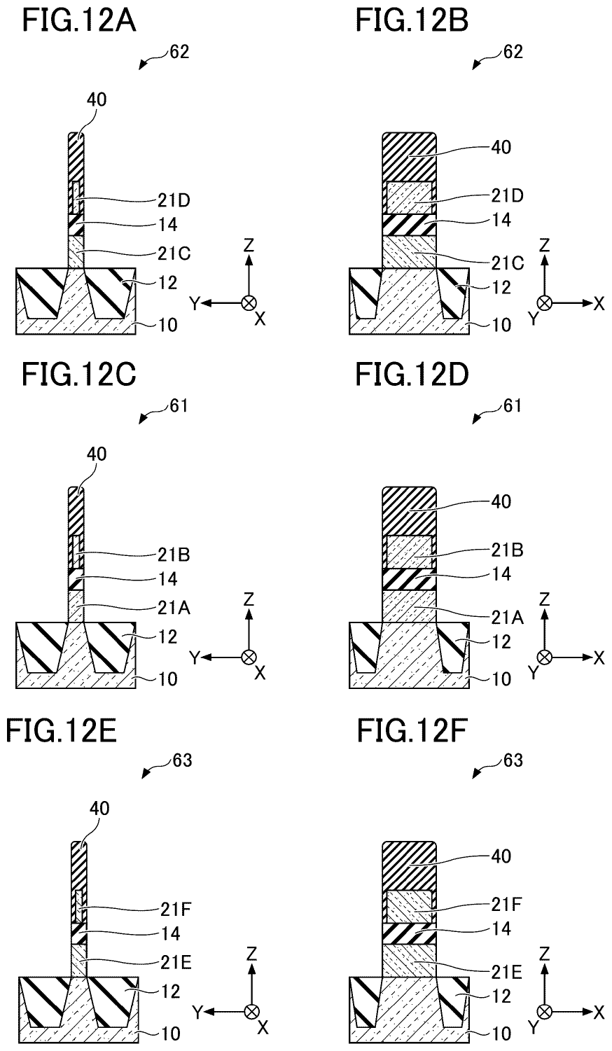

As shown in FIGS. 12A to 12F, using the mask layer 40 as a mask, the insulating film 14, the semiconductor layers 31A, 31C, and 31E are processed by, for example, an etching method. Thus, channel semiconductor layers 21A, 21C, and 21E are formed from the semiconductor layers 31C, 31A, and 31E, respectively. The channel semiconductor layers 21A, 21C, and 21E have a fin structure. The channel semiconductor layers 21A, 21C, and 21E may be trimmed to narrow the widths of the channel semiconductor layers 21A, 21C, and 21E in the Y-direction so as to be equal to the widths of the channel semiconductor layers 21B, 21D, and 21F in the Y-direction. The widths of the channel semiconductor layers 21A, 21C, and 21E in the Y-direction may be, for example, 4 nm to 15 nm.

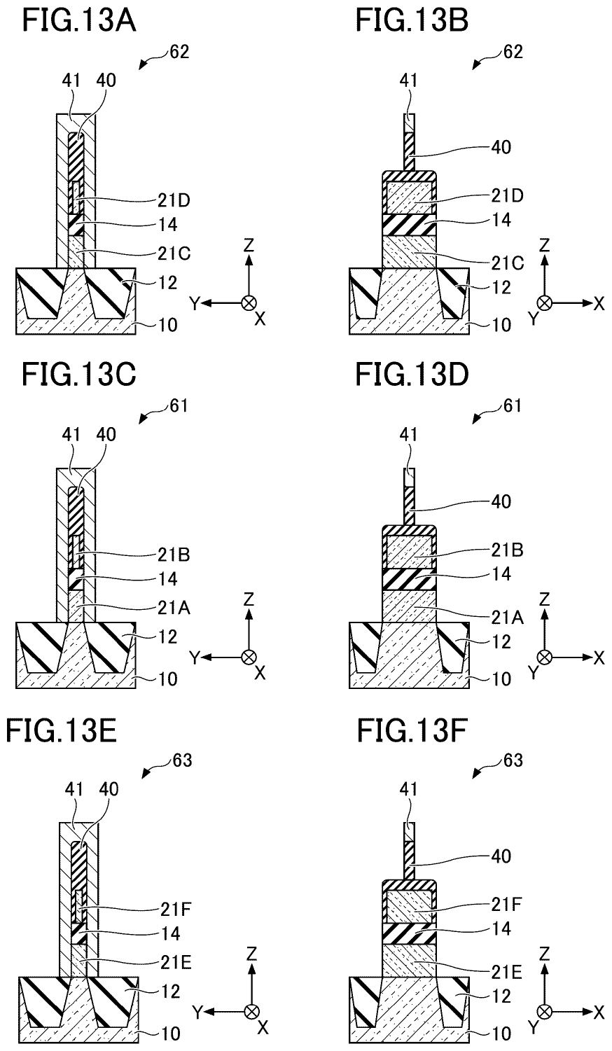

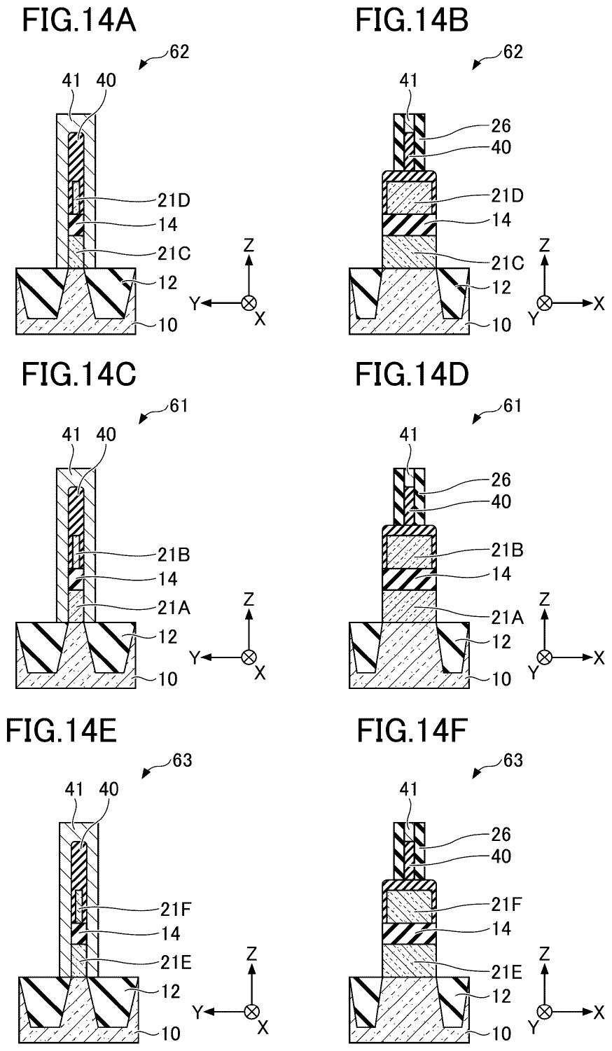

As shown in FIGS. 13A to 13F, a dummy gate 41 is formed in a region where a gate electrode is to be formed. As shown in FIGS. 13A, 13C, and 13E, the dummy gate 41 is provided on both sides of the mask layer 40, the insulating film 14, and the channel semiconductor layers 21A, 21C, and 21E in the Y-direction (see FIGS. 3A to 5B). As shown in FIGS. 13B, 13D, and 13F, the dummy gate 41 is provided on the mask layer 40. The dummy gate 41 is, for example, polycrystalline silicon.

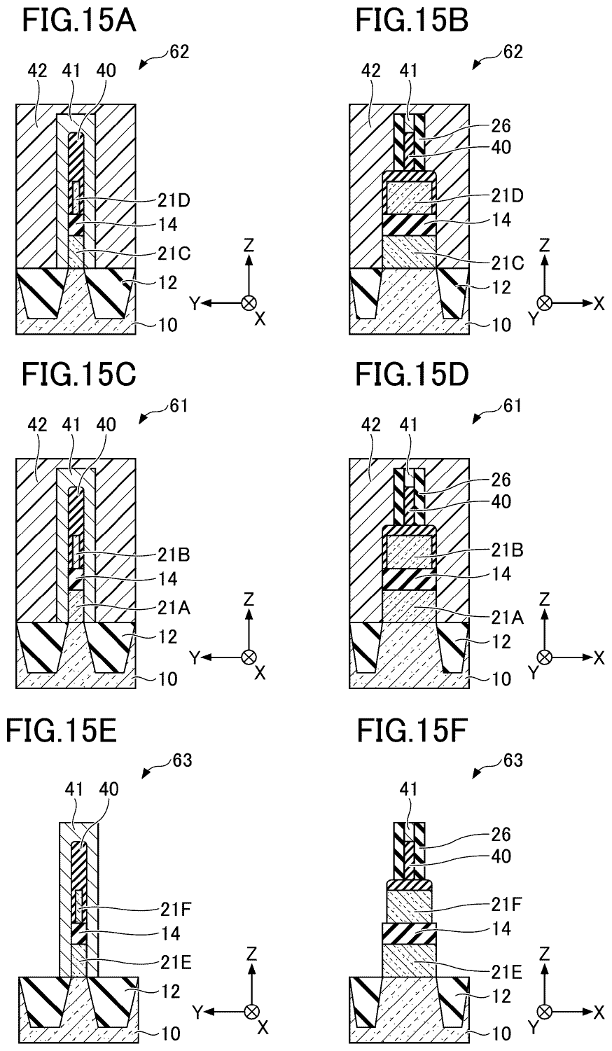

As shown in FIGS. 14A to 14F, a spacer 26 is formed so as to sandwich the dummy gate 41 in the X-direction. The spacer 26 is an insulating film such as a silicon nitride film or a silicon oxide film.

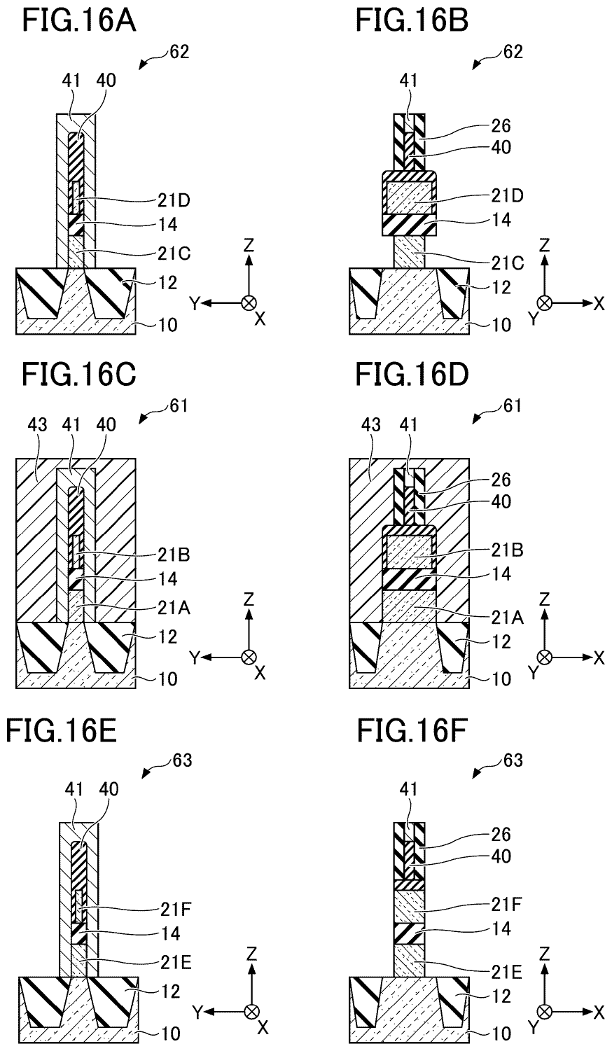

As shown in FIGS. 15A to 15F, a mask layer 42 is formed so as to cover the entire surface of the first region 61 and the second region 62. The third region 63 is exposed from the mask layer 42. The mask layer 42 is formed using, for example, a SOC (Spin On Carbon) method. The mask layer 40 is processed using the mask layer 42 as a mask. As a result, as shown in FIG. 15F, the mask layers 40 on both sides of the channel semiconductor layer 21F in the X-direction are removed. As a result, the lateral surfaces of the channel semiconductor layers 21C, 21E, and 21F are exposed from the mask layer 40 and the insulating film 14.

As shown in FIGS. 16A to 16F, after the mask layer 42 is removed, the mask layer 43 is formed so as to cover the entire surface of the first region 61. The second region 62 and the third region 63 are exposed from the mask layer 43. The mask layer 43 is formed by, for example, an SOC method. As shown in FIG. 16B, in the second region 62, both sides of the channel semiconductor layer 21C in the X-direction are removed using the mask layer 40 as a mask. As shown in FIG. 16F, in the third region 63, both sides of the channel semiconductor layers 21E and 21F in the X-direction are removed using the mask layer 43 as a mask. At this time, both sides of the insulating film 14 in the X-direction are also removed. As a result, both sides of the channel semiconductor layers 21C, 21F in the X-direction are exposed from the mask layer 40 and the insulating film 14.

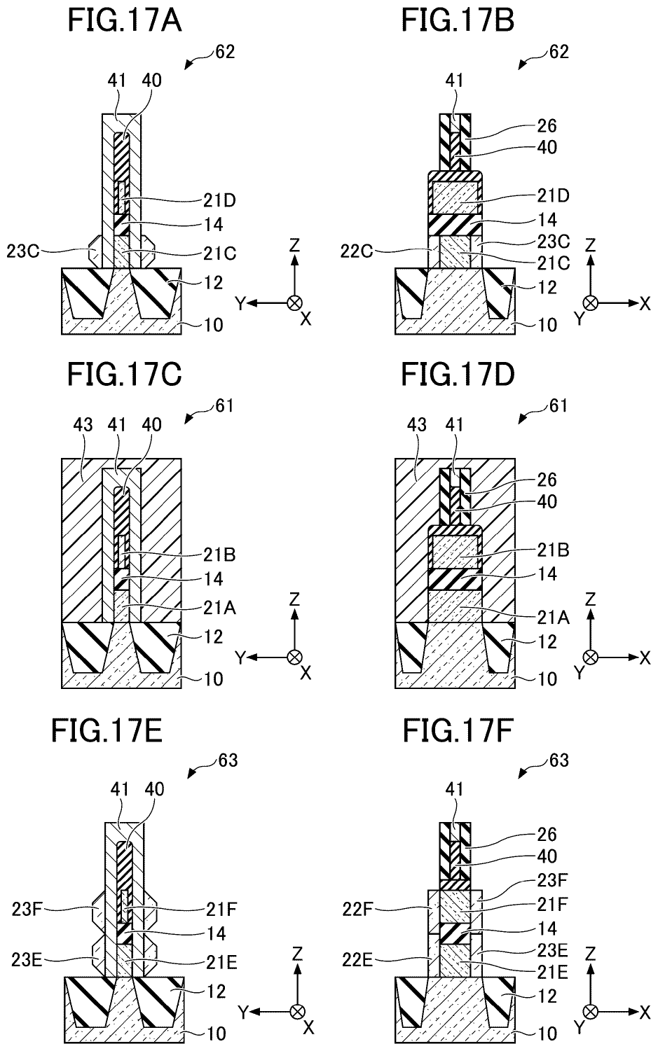

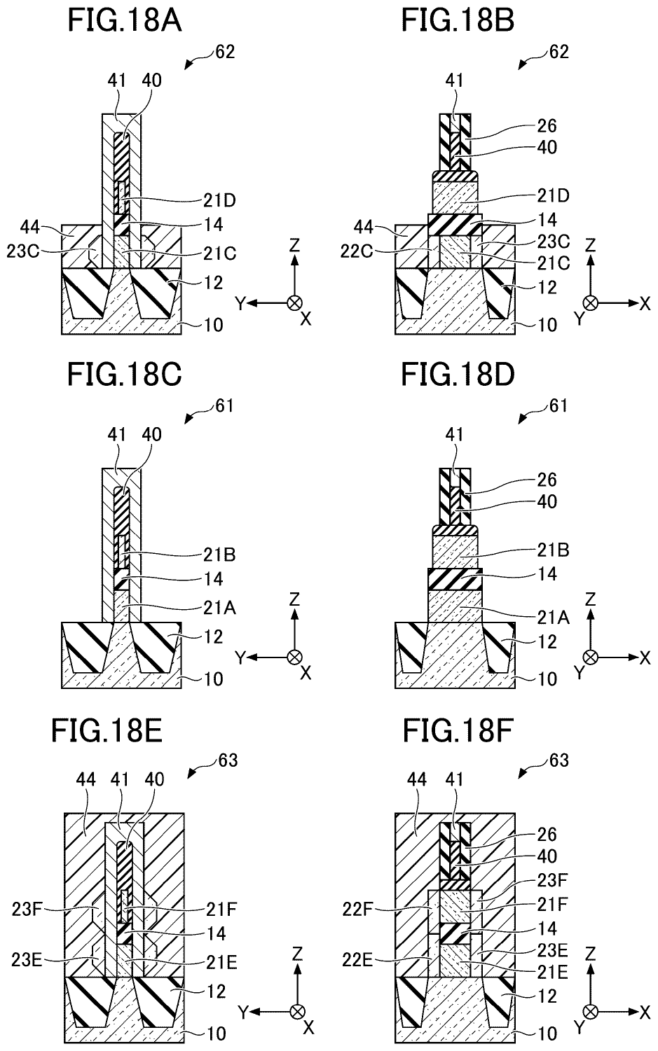

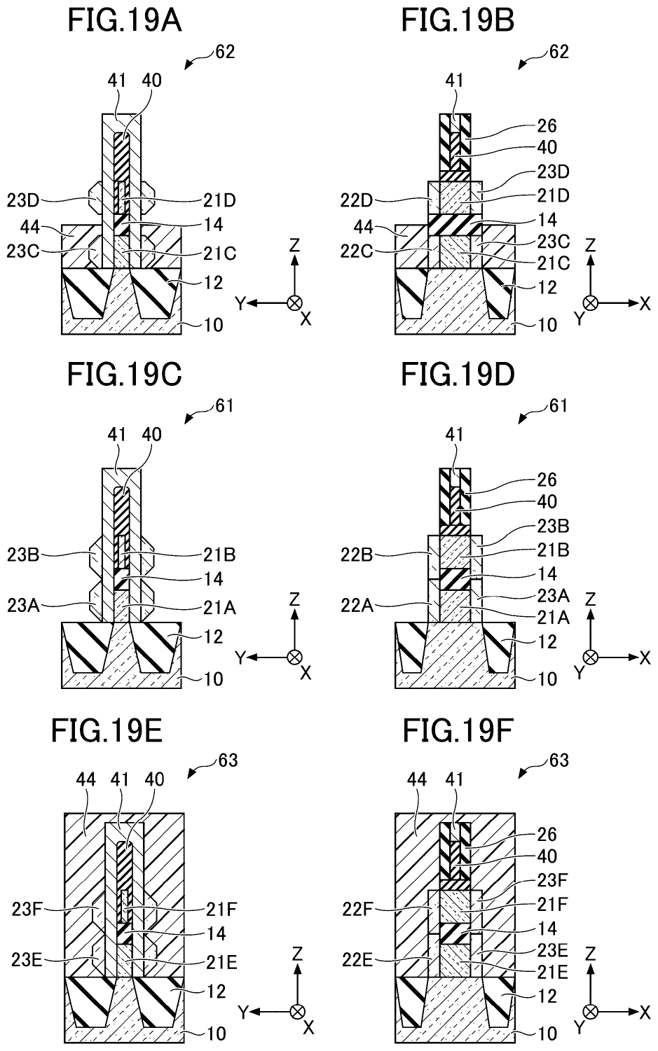

As shown in FIGS. 17A to 17F, source and drain semiconductor layers 22C, 23C, 22E, 23E, 22F, and 23F are epitaxially grown on the lateral surfaces of the channel semiconductor layers 21C, 21E, and 21F. As shown in FIG. 17B, in the second region 62, the top surfaces of the source and drain semiconductor layers 22C and 23C are defined by the insulating film 14. As shown in FIGS. 17E and 17F, since the lateral surfaces of the insulating film 14 are positioned at the same level as the lateral surfaces of the channel semiconductor layers 21E and 21F, the source and drain semiconductor layers 22E and 22F are brought into contact with each other, and the source and drain semiconductor layers 23E and 23F are brought into contact with each other, if the epitaxial conditions are appropriately set. Dopants may be ion-implanted into the surfaces of the source and drain semiconductor layers 22C, 23C, 22E, 23E, 22F, and 23F. Thus, contact layers with low resistivity can be formed on the surfaces of the source and drain semiconductor layers 22C, 23C, 22E, 23E, 22F, and 23F.

As shown in FIGS. 18A to 18F, after the mask layer 43 is removed, a mask layer 44 is formed so as to cover a portion of the second region 62 below the insulating film 14 and cover the entire surface of the third region. The first region 61 and a portion above the insulating film 14 of the second region 62 are exposed from the mask layer 44. The mask layer 44 is formed by, for example, an SOC method. As shown in FIG. 18B, in the second region 62, mask layers 40 on both sides in the X-direction of the channel semiconductor layer 21C are removed using the mask layer 44 as a mask. As shown in FIG. 18D, in the first region 61, mask layers 40 on both sides in the X-direction of the channel semiconductor layer 21B are removed using mask layer 44 as a mask. Thus, both sides of the channel semiconductor layers 21A, 21B and 21D in the X-direction are exposed from mask layer 40 and insulating film 14.

As shown in FIGS. 19A to 19F, the source and drain semiconductor layers 22A, 23A, 22B, 23B, 22D, and 23D are epitaxially grown on the lateral surfaces of the channel semiconductor layers 21A, 21B, and 21D. As shown in FIG. 19B, in the second region 62, the lower surfaces of the source and drain semiconductor layers 22D and 23D are defined by an insulating film 14. As shown in FIGS. 19C and 19D, if the epitaxial conditions are set appropriately, the source and drain semiconductor layers 22A and 22B are brought into contact, and the source and drain semiconductor layers 23A and 23B are brought into contact. Dopants may be ion-implanted into the surfaces of the source and drain semiconductor layers 22A, 23A, 22B, 23B, 22D, and 23D. Thus, contact layers with low resistivity can be formed on the surfaces of the source and drain semiconductor layers 22A, 23A, 22B, 23B, 22D, and 23D.

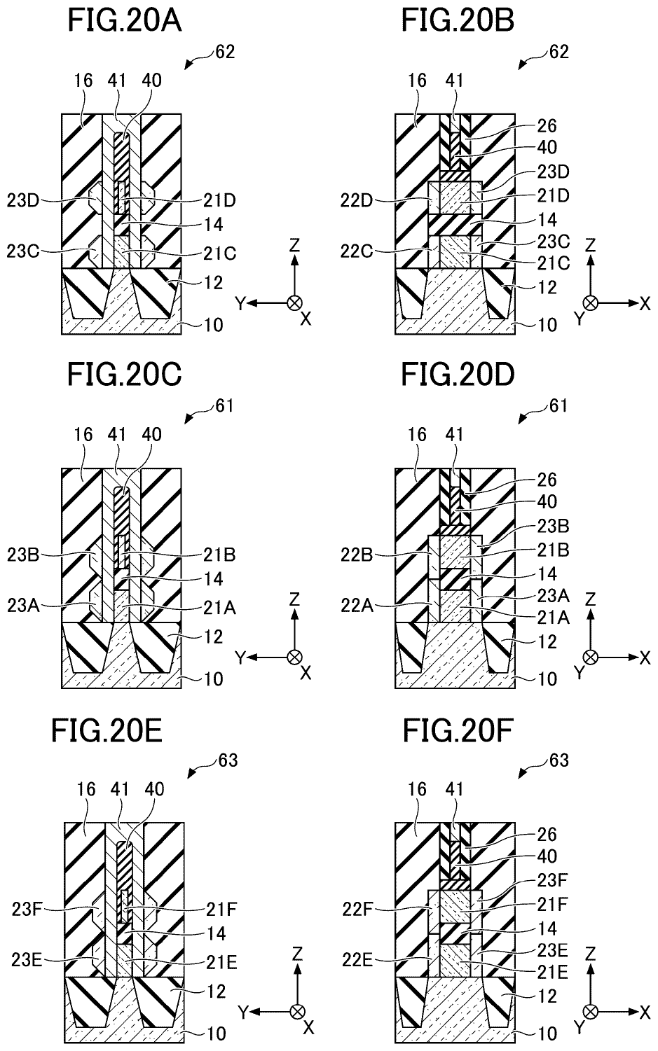

As shown in FIGS. 20A to 20F, after the mask layer 44 is removed, an insulating film 16 is formed on the substrate 10 so as to cover the entire structure. A dummy gate 41 is exposed from the upper surface of the insulating film 16.

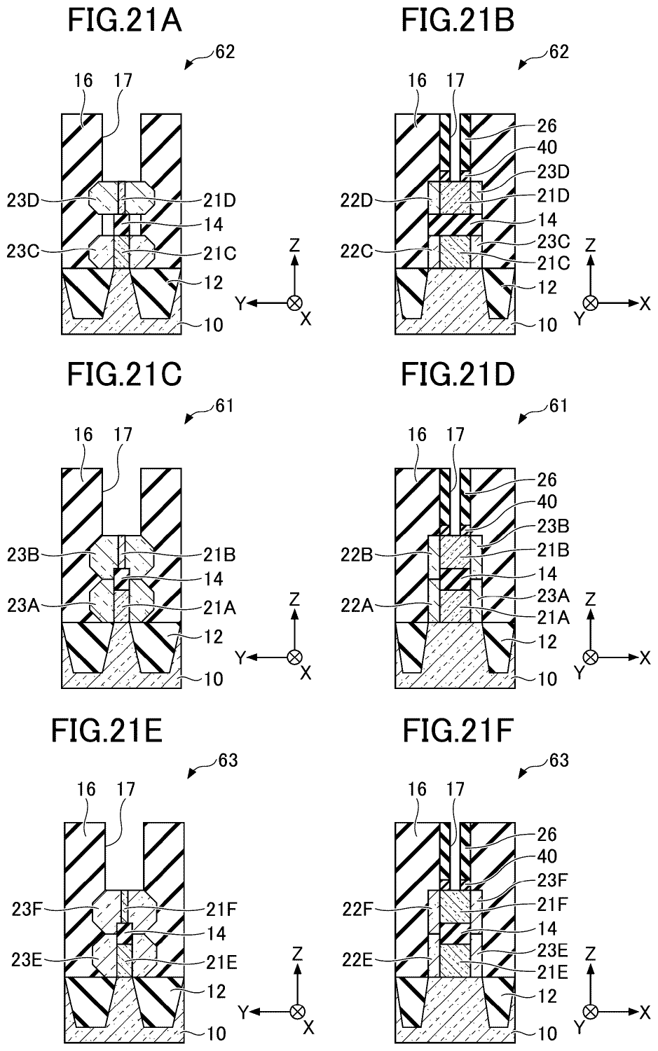

As shown in FIGS. 21A to 21F, the dummy gate 41 is selectively removed to form an opening 17 in the insulating film 16. There is a gap in the opening 17.

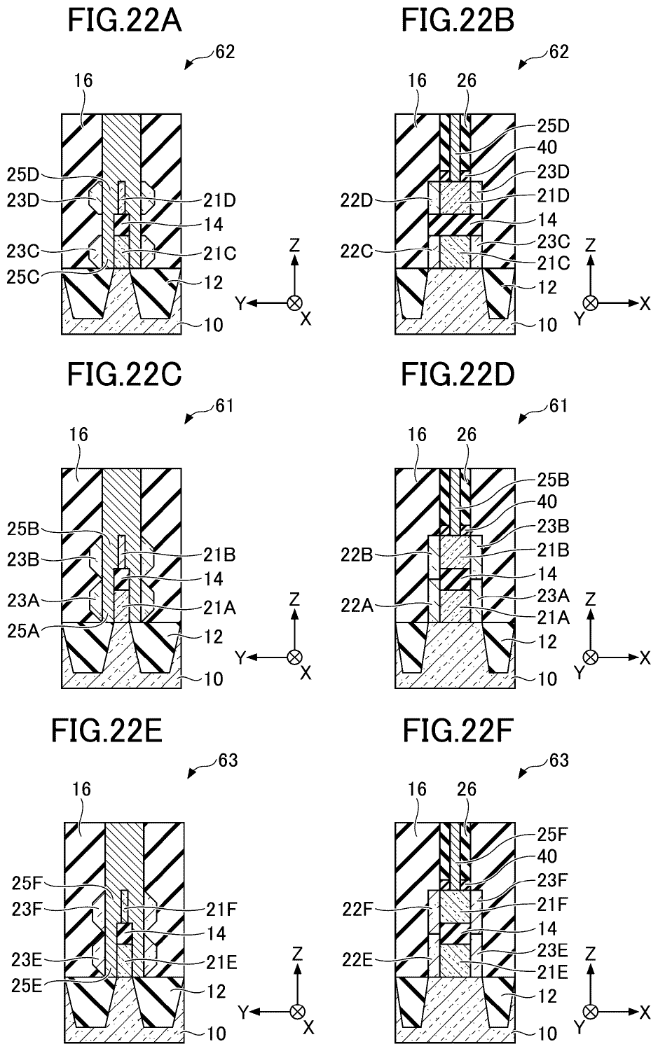

As shown in FIGS. 22A to 22F, a gate insulating film (not shown) and gate electrodes 25A to 25F are formed in the opening 17. A metal film for adjusting the work function may be formed between the gate insulating film and the gate electrodes 25A to 25F.

As shown in FIGS. 23A to 23F, a contact opening penetrating at least a part of the insulating film 16 is formed, and a contact 28 is formed in the contact opening. The contact 28 contacts at least one of the source and drain semiconductor layers 22A to 22F and 23A to 23F. Subsequently, an interlayer insulating film and wiring are formed on the insulating film 16, and a semiconductor device is manufactured.

### Manufacturing Method Two of First Embodiment

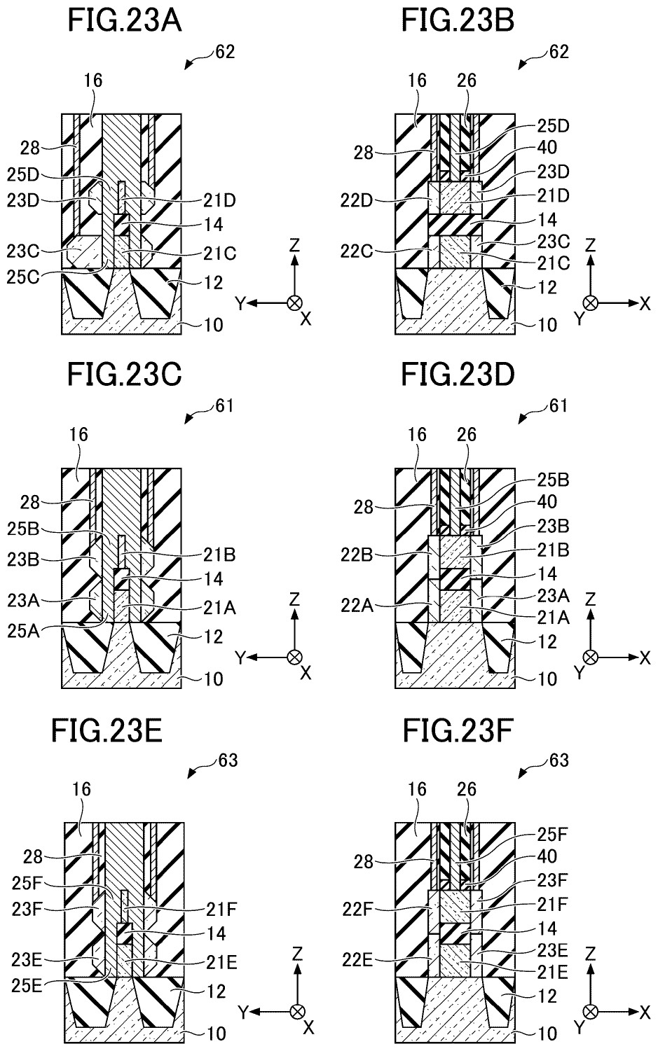

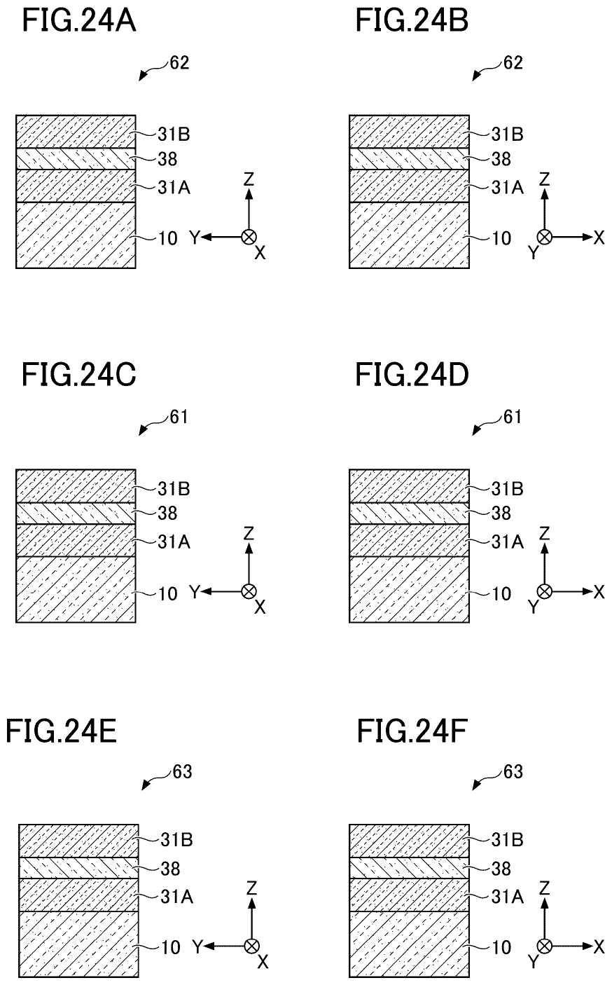

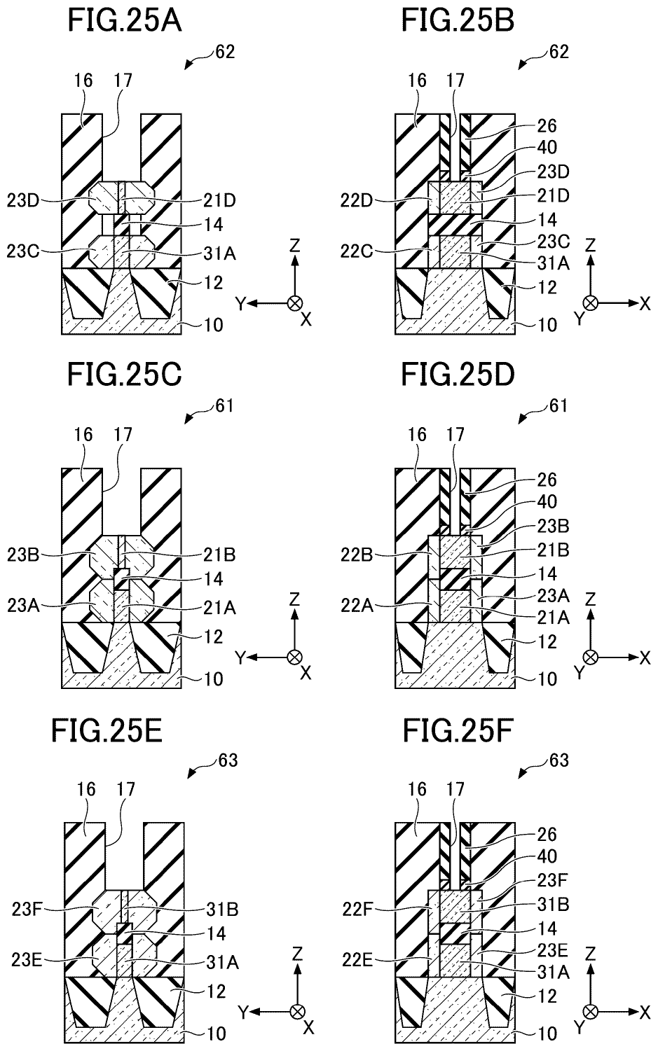

FIGS. 24A to 24F and 25A to 25F are cross-sectional views illustrating a manufacturing method two of the semiconductor device according to the first embodiment. In FIGS. 24A to 24F, the semiconductor layers 31A, 31C, and 31E are the same semiconductor layer 31A, and the semiconductor layers 31B, 31D, and 31F are the same semiconductor layer 31B.

Then, steps of FIGS. 8A to 8F to 20A to 20F are performed. At this time, in FIGS. 10A to 10F, a channel semiconductor layer 21B is formed from the semiconductor layer 31B in the first region 61, and a channel semiconductor layer 21D is formed from the semiconductor layer 31B in the second region 62. In FIGS. 12A to 12F, a channel semiconductor layer 21A is formed from the semiconductor layer 31A in the first region 61.

In FIGS. 25A to 25F, a semiconductor layer 31A is provided between the source and drain semiconductor layers 22C and 23C in the second region 62. In the third region 63, a semiconductor layer 31A is provided between the source and drain semiconductor layers 22E and 23E. A semiconductor layer 31B is provided between the source and drain semiconductor layers 22F and 23F. A part or all of the semiconductor layers 31A and 31B are removed, and then the channel semiconductor layers 21C, 21E, and 21F are epitaxially grown. Thus, the same structure as in FIGS. 21A to 21F is obtained. Subsequently, the semiconductor device according to the first embodiment can be manufactured by performing the steps of FIGS. 22A to 22F and 23A to 23F.

The channel semiconductor layers 21C, 21E, and 21F may be formed as illustrated in FIGS. 10A to 10F and 12A to 12F, and the channel semiconductor layers 21A, 21B, and 21D may be formed as illustrated in FIGS. 25A to 25F.

As in the manufacturing method one, the channel semiconductor layers 21A to 21F may be formed before the source and drain semiconductor layers 22A 23F are formed. As in to 22F and 23A to the manufacturing method two, at least a part of the channel semiconductor layers 21A to 21F may be formed after the source and drain semiconductor layers 22A to 22F and 23A to 23F are formed.

In the manufacturing methods one and two of the first embodiment, as in FIGS. 17A to 17F, a pair of source and drain semiconductor layers 22C and 23C (third source and drain semiconductor layers) of the P-type (first conductivity type) is formed on a substrate 10. As shown in FIGS. 19A to 19F, a pair of source and drain semiconductor layers 22A and 23A (first source and drain semiconductor layers) of the N-type (second conductivity type), a pair of source and drain semiconductor layers 22B and 23B (second source and drain semiconductor layers) of the N-type, and a pair of source and drain semiconductor layers 22D and 23D (fourth source and drain semiconductor layers) of the N-type are simultaneously formed. Thus, the transistor Tr1 of the second conductivity type channel can be formed in the first region 61, and the transistor Tr2 of the first conductivity type channel and the transistor Tr2 of the second conductivity type channel can be formed in the second region 62.

In the manufacturing method one, the channel semiconductor layers 21A to 21D are formed in FIGS. 10A to 10F and 12A to 12F, but in the manufacturing method two, the semiconductor layers 31A or 31B may be formed instead of the channel semiconductor layers 21A to 21D. Thus, the source and drain semiconductor layers 22A and 23A may sandwich the first semiconductor layer, the source and drain semiconductor layers 22B and 23B may sandwich the second semiconductor layer, the source and drain semiconductor layers 22C and 23C may sandwich the third semiconductor layer, and the source and drain semiconductor layers 22D and 23D may sandwich the fourth semiconductor layer.

Also, as shown in FIGS. 17A to 17F, a pair of source and drain semiconductor layers 22E and 23E (first source and drain semiconductor layers) of the P-type (second conductivity type), a pair of source and drain semiconductor layers 22F and 23F (second source and drain semiconductor layers) of the P-type, and a pair of source and drain semiconductor layers 22C and 23C (third source and drain semiconductor layers) of the P-type are simultaneously formed. As shown in FIGS. 19A to 19F, a pair of source and drain semiconductor layers 22D and 23D (fourth source and drain semiconductor layers) of the N-type (first conductivity type) are formed. Thus, a transistor Tr4 of the first conductivity type channel can be formed in the third region 63, and a transistor Tr2 of the first conductivity type channel and a transistor Tr2 of the second conductivity type channel can be formed in the second region 62.

In the manufacturing method one, channel semiconductor layers 21C to 21F are formed in FIGS. 10A to 10F and 12A to 12F, but in the manufacturing method two, semiconductor layers 31A or 31B may be formed instead of channel semiconductor layers 21C to 21F. As described above, source and drain semiconductor layers 22E and 23E sandwich the first semiconductor layer, the source and drain semiconductor layers 22F and 23F sandwich the second semiconductor layer, the source and drain semiconductor layers 22C and 23C sandwich the third semiconductor layer, and the source and drain semiconductor layers 22D and 23D sandwich the fourth semiconductor layer.

As in the manufacturing method two, after the source and drain semiconductor layers 22A to 22E and 22F to 23F are formed, at least one semiconductor layer of semiconductor layers 31A and 31B in the first region 61, the second region 62 and the third region 63 may be removed, and at least one channel semiconductor layer of corresponding channel semiconductor layers 21A to 21F may be formed in the region where at least one semiconductor layer is removed.

In FIG. 3A, the height of the top surface of the channel semiconductor layer 21C from the top surface of the substrate 10 is HC, and the respective heights of the bottom and top surfaces of the channel semiconductor layer 21D from the top surface of the substrate 10 are Hd and HD. The height of the top surface of the gate electrode 25D from the top surface of the substrate 10 is H2. In FIG. 4A, the height of the top surface of the channel semiconductor layer 21A from the top surface of the substrate 10 is HA, and the respective heights of the bottom and top surfaces of the channel semiconductor layer 21B from the top surface of the substrate 10 are Hb and HB. The height of the top surface of the gate electrode 25B from the top surface of the substrate 10 is H1. In FIG. 5A, the height of the top surface of the channel semiconductor layer 21E from the top surface of the substrate 10 is HE, and the respective heights of the bottom and top surfaces of the channel semiconductor layer 21F from the top surface of the substrate 10 are Hf and HF. The height of the top surface of the gate electrode 25F from the top surface of the substrate 10 is H3. The heights HA to HF correspond to the heights from the substrate 10 where the channel semiconductor layers 21A to 21F are farthest from the substrate 10, respectively. The heights Hb, Hd and Hf correspond to the heights from the substrate 10 where the channel semiconductor layers 21B, 21D and 21F are closest to the substrate 10, respectively. The heights H1 to H3 correspond to the heights from the substrate 10 where the gate electrodes 25B, 25D, and 25F are farthest from the substrate 10, respectively.

In the manufacturing methods one and two, a fine lithography technology such as EUVL (Extreme Ultraviolet Lithography) is used. EUVL has a very shallow depth of focus. In FIGS. 10A to 10F, in order to improve fabrication precision of the channel semiconductor layers 21B and 21D, an absolute value |HB−HD| of the difference between the heights HB (first height) and HD (second height) is preferably less than or equal to 0.1 times the height HB, and is preferably less than or equal to 0.05 times the height HB. |HB−HD| is preferably less than or equal to 10 nm, and more preferably less than or equal to 2 nm. The difference MAX−MIN between the maximum value MAX(HB, HD, HF) and the minimum value MIN(HB, HD, HF) of the heights HB, HD, and HF is preferably less than or equal to 0.1 times the maximum value MAX, and is preferably less than or equal to 0.05 times the maximum value MAX. MAX−MIN is preferably less than or equal to 10 nm, and more preferably less than or equal to 2 nm.

In FIGS. 13A to 13F, in order to improve fabrication precision of the dummy gate 41, the difference MAX−MIN between the maximum value MAX(H1, H2, H3) and the minimum value MIN(H1, H2, H3) of the heights H1, H2, and H3 is preferably less than or equal to 0.1 times the maximum value MAX, and more preferably less than or equal to 0.05 times. MAX−MIN is preferably less than or equal to 10 nm, and more preferably less than or equal to 2 nm.

If the heights HA, HC, and HE are not uniform, or the heights Hb, Hd, and Hf are not uniform, the parasitic capacitance of the gate electrode varies, and the aspect ratio of the contact 28 varies. In order to suppress these variations, the difference MAX−MIN between the maximum value MAX(HA, HC, HE) and the minimum value MIN(HA, HC, HE) is preferably less than or equal to 0.1 times the maximum value MAX, and more preferably less than or equal to 0.05 times. MAX−MIN is preferably less than or equal to 10 nm, and more preferably less than or equal to 2 nm. The difference MAX−MIN between the maximum value MAX(Hb, Hd, Hf) and the minimum value MIN(Hb, Hd, Hf) is preferably less than or equal to 0.1 times the maximum value MAX, and more preferably less than or equal to 0.05 times the maximum value MAX. MAX−MIN is preferably less than or equal to 10 nm, and more preferably less than or equal to 2 nm.

### First Modification of First Embodiment

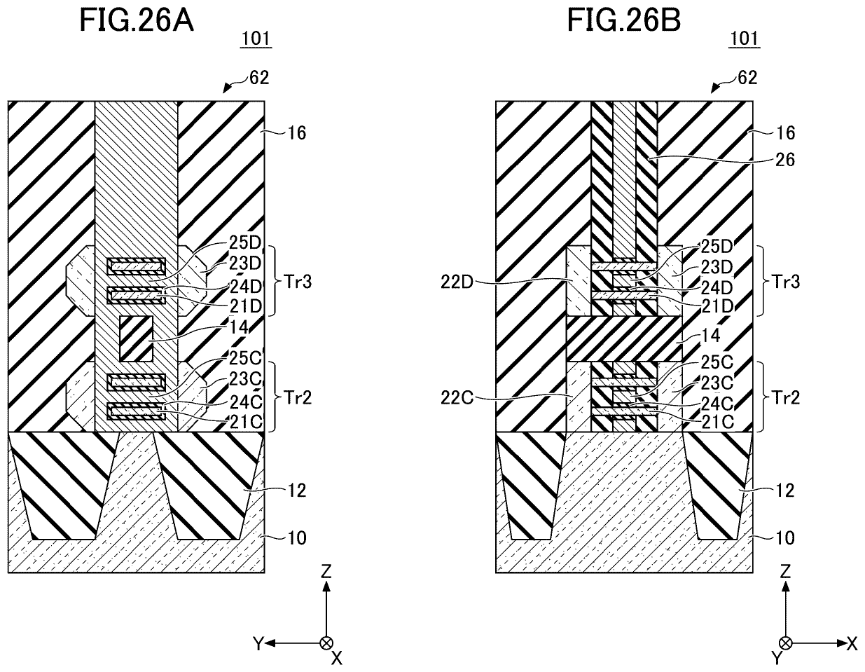

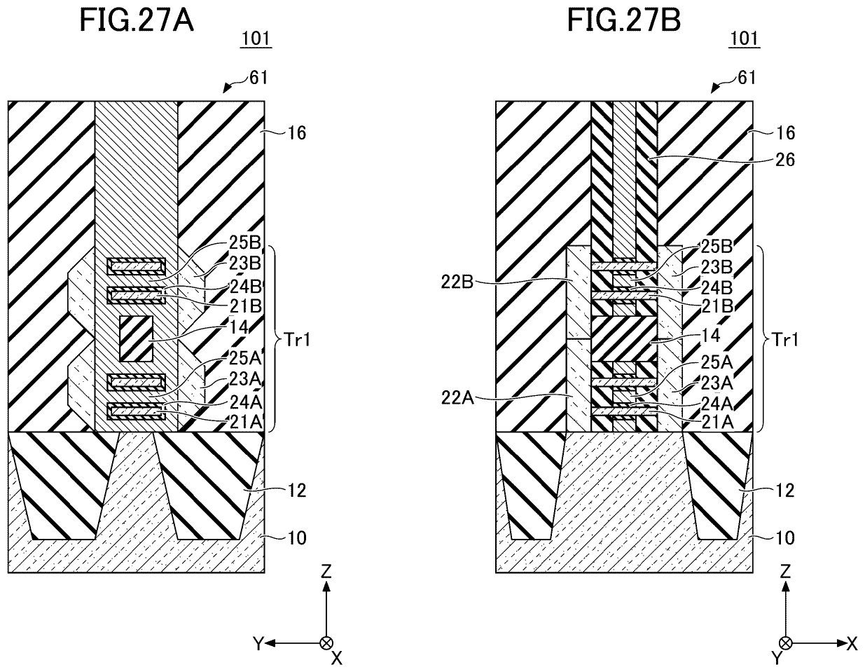

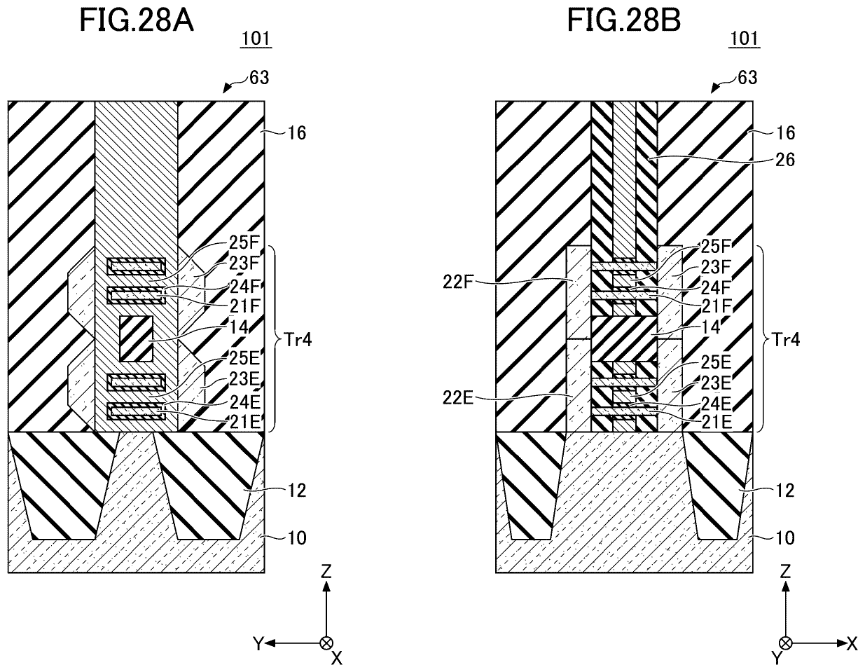

A first modification of the first embodiment is an example in which nanosheet transistors are used as transistors Tr1 to Tr4. FIGS. 26A and 26B are cross-sectional views illustrating a second region first modification of the first according to the embodiment. FIGS. 27A and 27B are cross-sectional views illustrating a first region according to the first modification of the first embodiment. FIGS. 28A and 28B are cross-sectional views illustrating a third region according to the first modification of the first embodiment.

As shown in FIGS. 26A to 28B, in the semiconductor device 101 according to the first modification of the first embodiment, a plurality of channel semiconductor layers 21A to 21F are provided in the Z-direction. Gate insulating films 24A to 24F are provided so as to surround channel semiconductor layers 21A to 21F, respectively. Gate electrodes 25A to 25F are provided so as to sandwich gate insulating films 24A to 24F and surround channel semiconductor layers 21A to 21F, respectively. The thickness of the channel semiconductor layers 21A to 21F in the Z-direction is, for example, 4 nm to 15 nm, and each distance between the channel semiconductor layers 21A to 21F in the Z-direction is, for example, 4 nm to 15 nm. Although an example in which two channel semiconductor layers 21A to 21F are provided in the Z-direction has been described, three or more channel semiconductor layers 21A to 21F may be provided in the Z-direction. Other configurations are the same as those in the first embodiment, and their descriptions will be omitted.

### Second Modification of First Embodiment

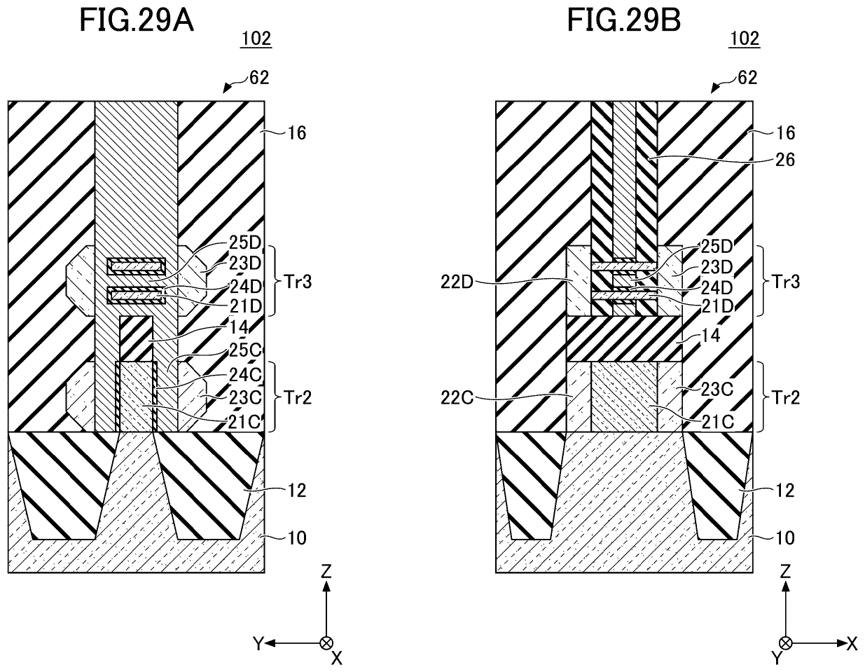

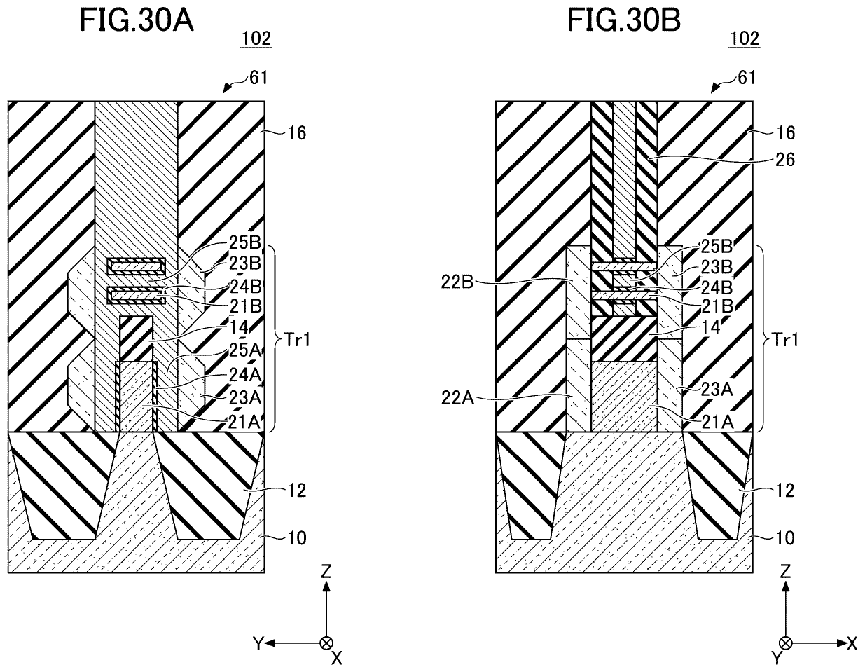

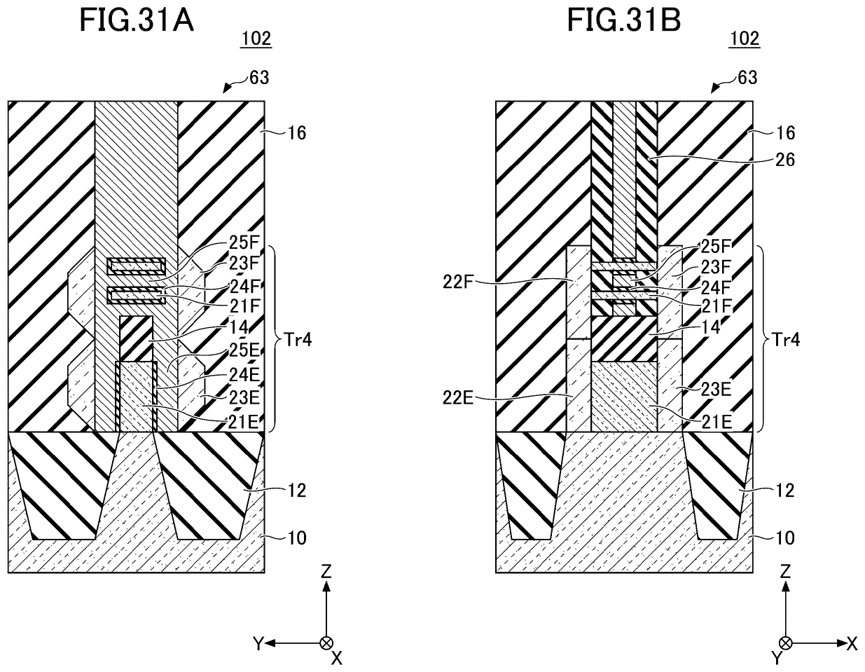

A second modification of the first embodiment is an example in which a part of the transistor Tr1, a part of the transistor Tr4, and the transistor Tr2 are FinFETs, and a part of the transistor Tr1, a part of the transistor Tr4, and the transistor Tr3 are nanosheet transistors. FIGS. 29A and 29B are cross-sectional views illustrating a second region according to the second modification of the first embodiment. FIGS. 30A and 30B are cross-sectional views illustrating a first region according to the second modification of the first embodiment. FIGS. 31A and 31B are cross-sectional views illustrating a third region according to the second modification of the first embodiment.

As shown in FIGS. 29A to 31B, in the semiconductor device 102 according to the second modification of the first embodiment, the channel semiconductor layers 21A, 21C, and 21E have a fin structure, and the channel semiconductor layers 21B, 21D, and 21F are each provided in a plurality of nanosheet structures in the Z-direction. Each of the channel semiconductor layers 21B, 21D, and 21F may be provided with three or more layers in the Z-direction. Other structures are the same as those of the first embodiment and the first modification of the first embodiment, and their descriptions will be omitted.

As in the first embodiment and the first and second modifications of the first embodiment, at least one of the channel semiconductor layers 21A to 21F may have a fin structure, and at least one of the channel semiconductor layers 21A to 21F may have a nanosheet structure. It is preferable that the channel semiconductor layers 21A, 21C, and 21E have the same fin structure or the same nanosheet structure, and that the channel semiconductor layers 21B, 21D, and 21F have the same fin structure or the same nanosheet structure. Thus, manufacturing of the channel semiconductor layers to 21A 21F is facilitated.

Electron mobility of silicon is 130 cm²V⁻¹s⁻¹ in a (110) plane direction and 307 cm²V⁻¹s⁻¹ in a (100) plane direction. Hole mobility of silicon is 238 cm²V⁻¹s⁻¹ in the (110) plane direction and 78 cm²V⁻¹s⁻¹ in the (100) plane direction. If the substrate 10 is a silicon substrate whose main surface is the (100) plane of crystal orientation, a carrier travel direction is the (110) plane direction in the fin structure, and the carrier travel direction is the (100) plane direction in the nanosheet structure. Therefore, it is preferable that the channel semiconductor layer has a fin structure in the P-type channel transistor, and the channel semiconductor layer has a nanosheet structure in the N-type channel transistor.

High-speed CFETs in the second region 62 are often required. Therefore, one of the channel semiconductor layers 21A and 21C and the channel semiconductor layers 21B and 21D has a fin structure, and the other has a nanosheet structure. Among the channel semiconductor layers 21C and 21D, the channel semiconductor layer having a fin structure is the N-type. This makes it possible to speed up the CFETs in the second region 62. It is preferable that the channel semiconductor layer having a fin structure be a P-type when the magnitude relationship between the electron mobility and the hole mobility is reversed (e.g., when a silicon substrate having the (110) plane as the main surface is used). In CFETs, the transistor Tr2 is often a P-type channel transistor and the transistor Tr3 is often an N-type channel transistor. Therefore, it is preferable that the channel semiconductor layers 21A, 21C, and 21E have a fin structure and the channel semiconductor layers 21B, 21D, and 21F have a nanosheet structure.

### Third Modification of First Embodiment

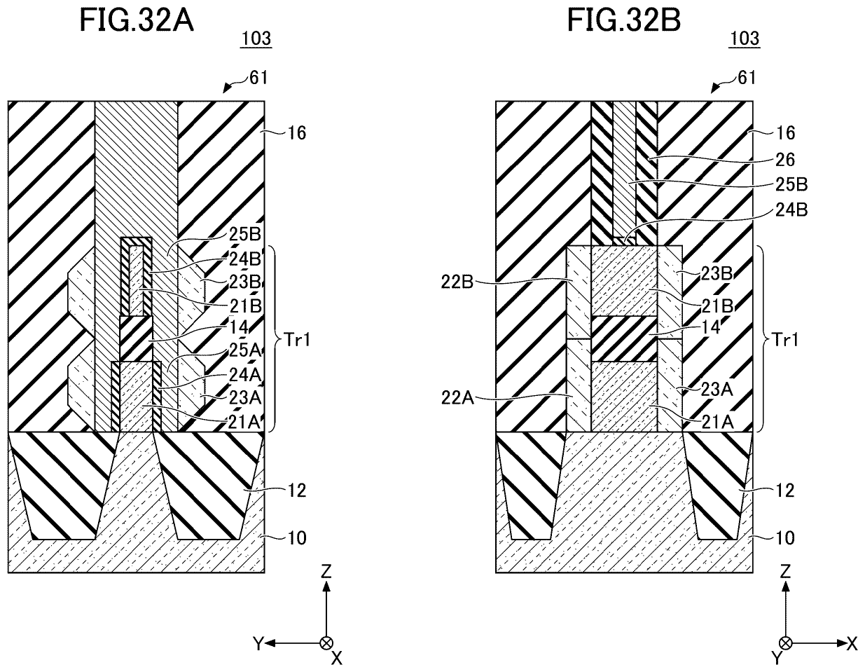

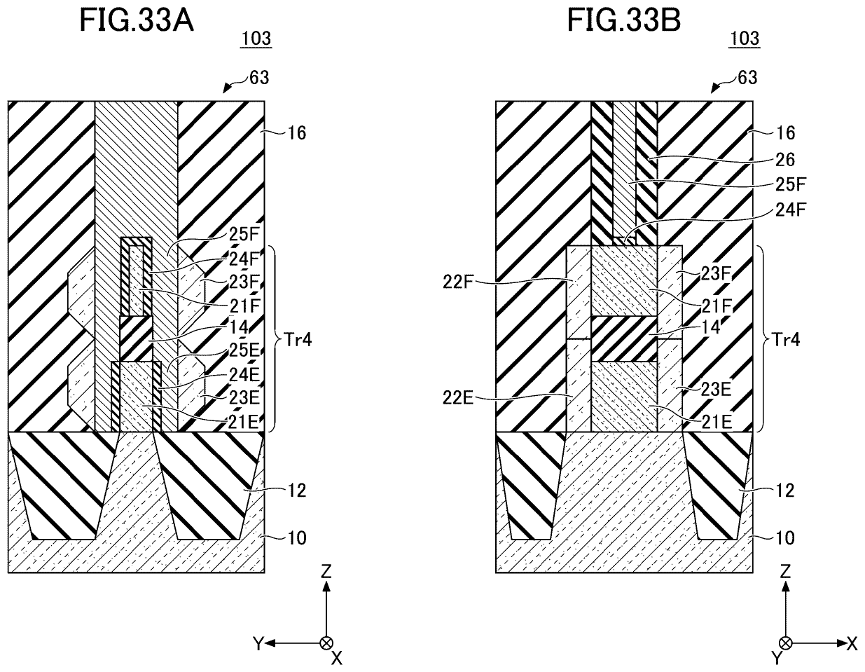

A third modification of the first embodiment is an example in which the gate insulating films of the transistors Tr1 and Tr4 are thicker than the gate insulating films of the transistors Tr2 and Tr3 in the FinFET. FIGS. 32A and 32B are cross-sectional views illustrating a first region according to a third modification of the first embodiment. FIGS. 33A and 33B are cross-sectional views illustrating a third region according to the third modification of the first embodiment. The cross sections of the second region 62 are the same as those of FIGS. 3A and 3B.

As shown in FIGS. 32A to 33B, in the semiconductor device 103 according to the third modification of the first embodiment, the gate insulating films 24A, 24B, 24E, and 24F are thicker than the gate insulating films 24C and 24D in FIGS. 3A and 3B. The other configurations are the same as those of the first embodiment, and their descriptions will be omitted.

### Fourth Modification of First Embodiment

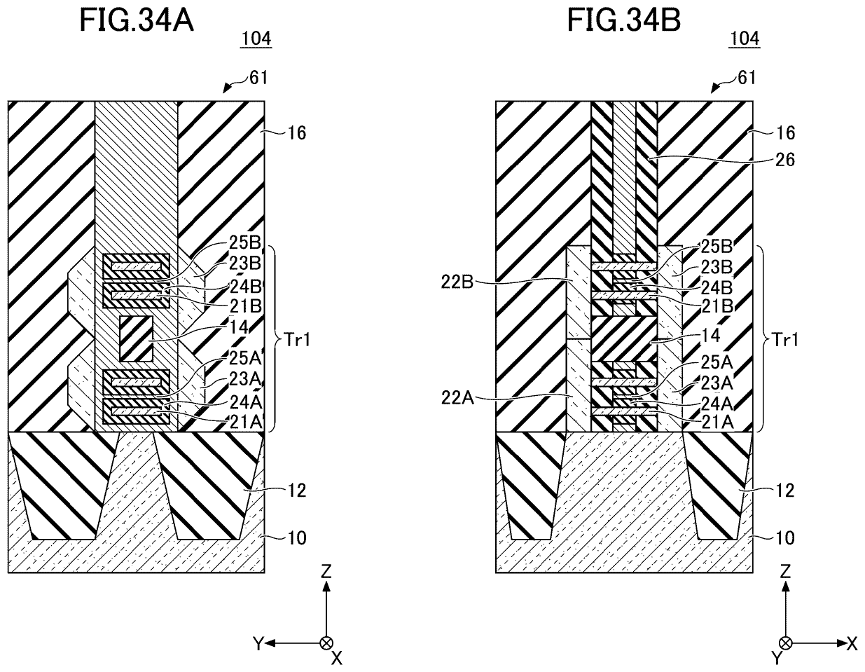

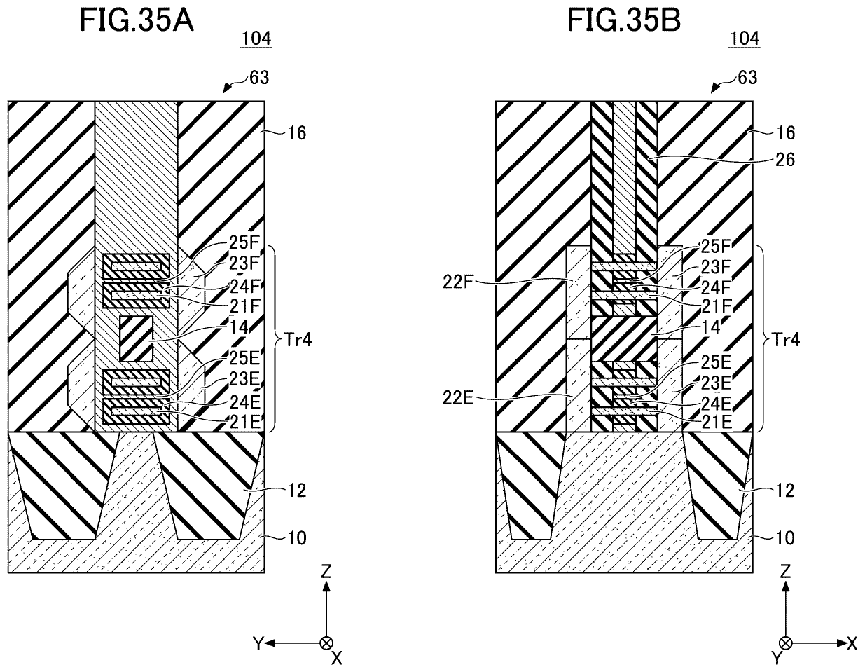

A fourth modification of the first embodiment is an example in which the gate insulating films of the transistors Tr1 and Tr4 are thicker than the gate insulating films of the transistors Tr2 and Tr3 in the nanosheet transistor. FIGS. 34A and 34B are cross-sectional views illustrating a first region according to the fourth modification of the first embodiment. FIGS. 35A and 35B are cross-sectional views illustrating a third region according to the fourth modification of the first embodiment. The cross sections of the second region 62 are the same as those of FIGS. 26A and 26B.

As shown in FIGS. 34A to 35B, in the semiconductor device 104 according to the fourth the first embodiment, the gate modification of insulating films 24A, 24B, 24E, and 24F are thicker than the gate insulating films 24C and 24D in FIGS. 26A and 26B. The other configurations are the same as those of the first modification of the first embodiment, and their descriptions will be omitted.

Since the transistors Tr1 and Tr4 are used in an input/output circuit, for example, voltages applied to the gate electrodes 25A, 25B, 25E, and 25F may be higher than voltages applied to the gate electrodes 25C and 25D of the transistors Tr2 and Tr3. As in the third and fourth modifications of the first embodiment, thicknesses of the gate insulating films 24A, 24B, and 24E, 24F are all greater than thicknesses of the gate insulating films 24C and 24D.

Thus, the breakdown voltage of the transistors Tr1 and Tr4 can be higher than that of the transistors Tr2 and Tr3. Additionally, since the gate insulating films 24C and 24D are thin, the transistors Tr2 and Tr3 can operate at high speed. The thicknesses of the gate insulating films 24A, 24B, 24E, and 24F are preferably 1.2 times or more than the thicknesses of the gate insulating films 24C and 24D, and more preferably 1.5 times or more. Even when FinFETs and nanosheet transistors are combined as in the second modification of the first embodiment, the gate insulating films 24A, 24B, 24E, and 24F may be made thicker than the gate insulating films 24C and 24D.

In the nanosheet transistor, as in the fourth modification of the first embodiment, distances between each of the channel semiconductor layers 21A (21B, 21E, and 21F) in the Z-direction are small. Therefore, when the gate insulating films 24A (24B, 24E, and 24F) are made thicker, thicknesses between the channel semiconductor layers 21A (21B, 21E, and 21F) of the gate electrode 25A (25B, 25E, and 25F) become smaller. Therefore, when the gate insulating films 24A, 24B, 24E, and 24F are made thicker than the gate insulating films 24C and 24D, the transistors Tr1 to Tr4 are preferably FinFETs as in the third modification of the first embodiment.

### Fifth Modification of First Embodiment

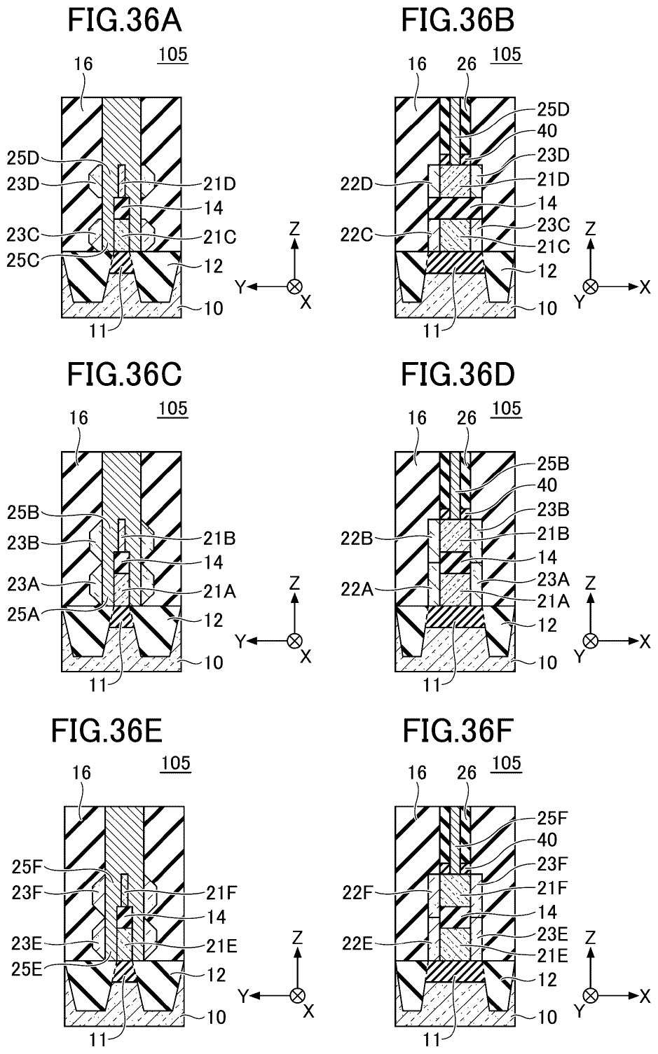

FIGS. 36A to 36F are cross-sectional views of the semiconductor device according to a fifth modification of the first embodiment. As shown in FIGS. 36A to 36F, in the semiconductor device 105 according to the fifth modification of the first embodiment, an insulating film 11 is provided between the channel semiconductor layers 21A, 21C, and 21E and the substrate 10. The insulating film 11 is, for example, a silicon oxide film. Other configurations are the same as those of the first embodiment, and their descriptions will be omitted. The insulating film 11 may also be provided in the first to fourth modifications of the first embodiment.

When the insulating film 11 is provided, as in the fifth modification of the first embodiment, leakage currents between the substrate 10 and the transistors Tr1, Tr2, and Tr4 can be prevented. When the channel semiconductor layers 21A, 21C, and 21D of the transistors Tr1, Tr2, and Tr4 are in contact with the substrate 10 without the insulating film 11, as in the first embodiment, the characteristics of the transistors Tr1, Tr2, and Tr4 can be controlled by controlling the potential of the substrate 10. When the insulating film 11 is not provided, it is preferable to prevent the leakage current by using a technology such as channel stop.

### Second Embodiment

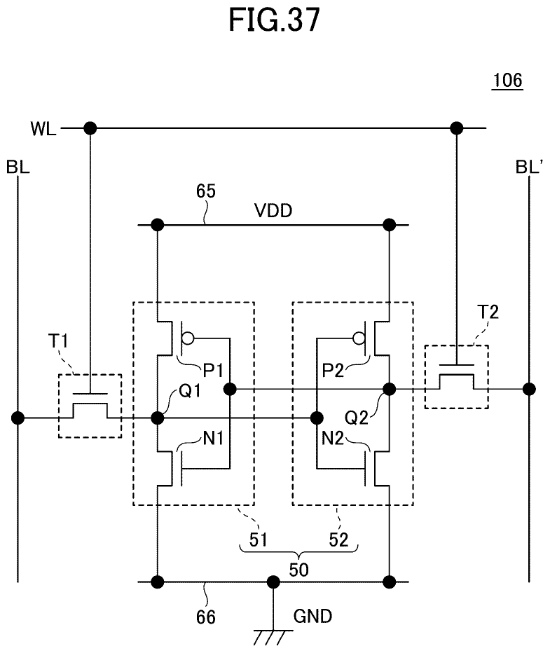

A second embodiment and its modification are examples of using the transistors Tr1 to Tr4 of the first embodiment and its modification a in semiconductor device having a circuit. The second embodiment is an example of using the transistors Tr1 to Tr3 in an SRAM (Static Random Access Memory) cell. FIG. 37 is a circuit diagram of the semiconductor device according to the second embodiment. As shown in FIG. 37, the semiconductor device 106 according to the second embodiment includes a bistable circuit 50 and passgate transistors T1 and T2. The bistable circuit 50 includes inverter circuits 51 and 52. The inverter circuit 51 includes NFETN1 and PFETP1. The source of NFETN1 is electrically connected to the ground line 66, and the source of PFETP1 is electrically connected to the power supply line 65. The drain of NFETN1 and the drain of PFETP1 are electrically connected to form an output node of the inverter circuit 51. The gate of NFETN1 and the gate of PFETP1 are electrically connected to form an input node of the inverter circuit 51.

The inverter circuit 52 includes NFETN2 and PFETP2. The source of NFETN2 is electrically connected to the ground line 66, and the source of PFETP2 is electrically connected to the power supply line 65. The drain of NFETN2 and the drain of PFETP2 are electrically connected to form an output node of the inverter circuit 52. The gate of NFETN2 and the gate of PFETP2 are electrically connected to form an input node of the inverter circuit 52. Ground voltage GND is supplied to the ground line 66, and supply voltage VDD is supplied to the power supply line 65.

The output node of the inverter circuit 51 and the input node of the inverter circuit 52 are electrically connected to form a storage node Q1. The input node of the inverter circuit 51 and the output node of the inverter circuit 52 are electrically connected to form a storage node Q2.

One of the source and drain of the passgate transistor T1 is electrically connected to the storage node Q1, and the other of the source and drain is electrically connected to a bit line BL. The gate of the passgate transistor T1 is electrically connected to a word line WL. One of the source and drain of the passgate transistor T2 is electrically connected to the storage node Q2, and the other of the source and drain is electrically connected to a bit line BL′. The gate of the passgate transistor T2 is electrically connected to the word line WL.

When data is written to the bistable circuit 50, the bit lines BL and BL′ are set to write potentials. The word line WL is set to a high level, and the passgate transistors T1 and T2 are turned on. Thus, the data of the bit lines BL and BL′ are written to the storage nodes Q1 and Q2, respectively. When data is read to the bistable circuit 50, the bit lines BL and BL′ are set to floating, the word line WL is set to a high level, and the passgate transistors T1 and T2 are turned on. Thus, the data of the storage nodes Q1 and Q2 are read out to the bit lines BL and BL′.

NFETN1 and N2 are defined as transistors Tr3 according to the first embodiment and its modification, PFETP1 and P2 are defined as transistors Tr2 according to the first embodiment and its modification, and passgate transistors T1 and T2 are defined as transistors Tr1 according to the first embodiment and its modification. Thus, the bistable circuit 50 includes a pair of inverter circuits 51 and 52 having transistors Tr2 and Tr3. The passgate transistors T1 and T2 are transistors Tr1 connected to the storage nodes Q1 and Q2. Thus, the driving capabilities of the passgate transistors T1 and T2 are approximately twice those of the NFETN1, N2, and PFETP1. Therefore, when data is written to the storage nodes Q1 and Q2, data can be written to the storage nodes Q1 and Q2 more reliably.

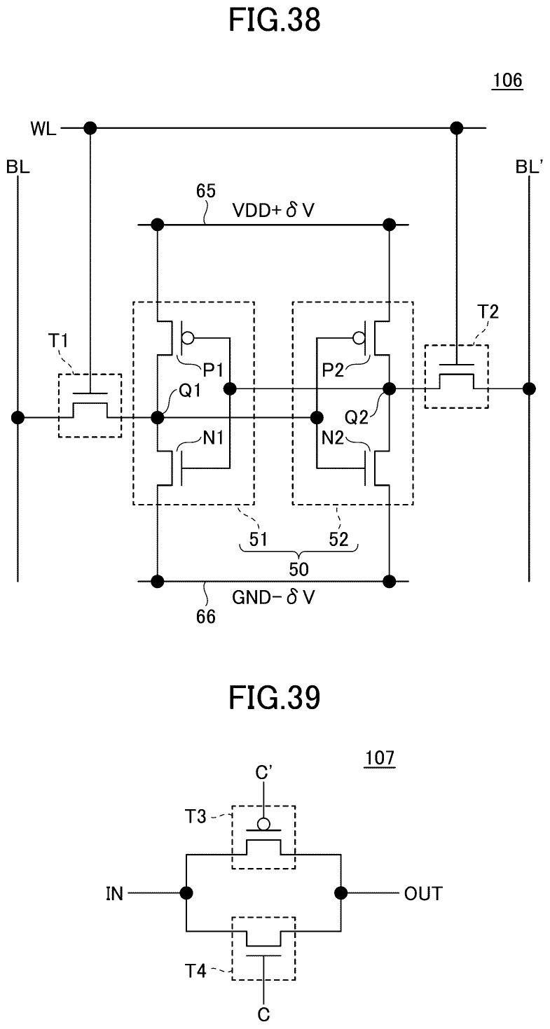

FIG. 38 is a circuit diagram of the semiconductor device according to the second embodiment. When data is read from the storage nodes Q1 and Q2, if the driving capabilities of the passgate transistors T1 and T2 are large, there is a possibility that the charges of the storage nodes Q1 and Q2 cannot charge or discharge the bit lines BL and BL′, and that the data of the storage nodes Q1 and Q2 might become inverted. Therefore, as shown in FIG. 38, when data is read out, the voltage of the power supply line 65 is set to VDD+δV higher than VDD, or the voltage of the ground line 66 is set to GND−δV lower than GND. Thus, data reading can be assisted (read assist). When data is held and data is written, the voltages of the power supply line 65 and the ground line 66 are VDD and GND, respectively, as shown in FIG. 37.

When CFET is used in the SRAM cell, the chip size can be decreased by approximately 0.8 times. Furthermore, by using transistor Tr1 as the passgate transistors T1 and T2, the chip size can be reduced without changing the passgate transistors T1 and T2.

### First Modification of Second Embodiment

A first modification of the second embodiment is an example of a transfer gate. FIG. 39 is a circuit diagram of a semiconductor device according to the first modification of the second embodiment. As shown in FIG. 39, the semiconductor device 107 according to the first modification of the second embodiment includes transistors T3 and T4. One of the source and drain of the transistor T3 is electrically connected to the input node IN, and the other of the source and drain is electrically connected to the output node OUT. A clock signal C′ is input to the gate of the transistor T3. One of the source and drain of the transistor T4 is electrically connected to the input node IN, and the other of the source and drain is electrically connected to the output node OUT. A clock signal C is input to the gate of the transistor T4. The clock signal C′ is an inverted signal of the clock signal C. Thus, when the clock signal C is at a high level, the input node IN and the output node OUT are electrically connected, and when the clock signal C is at a low level, the input node IN and the output node OUT are electrically disconnected.

The transistor T3 is the transistor Tr4 of the first embodiment and its modification, and the transistor T4 is the transistor Tr1 of the first embodiment and its modification. A large driving capability is required for the transfer gate. Therefore, transistors Tr1 and Tr4 are used for the transfer gate. Thus, the driving capability of the transfer gate can be improved. When a transfer gate with the same driving capability is used, the chip size can be reduced.

### Second Modification of Second Embodiment

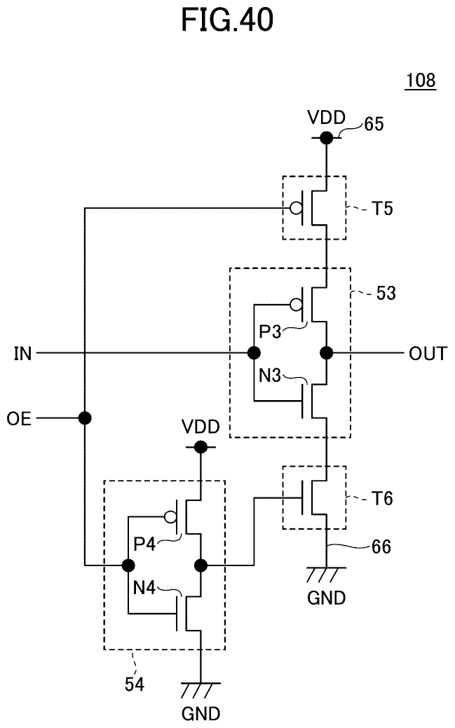

A second modification of the second embodiment is an example of a tri-state inverter. FIG. 40 is a circuit diagram of the semiconductor device according to the second modification of the second embodiment. As shown in FIG. 40, the semiconductor device 108 according to the second modification of the second embodiment includes inverter circuits 53 and 54 and transistors T5 and T6.

The inverter circuit 53 includes NFETN3 and PFETP3. The input node IN is electrically connected to the gates of NFETN3 and PFETP3, and the output node OUT is electrically connected to the drains of NFETN3 and PFETP3. The source of transistor T5 is electrically connected to the power supply line 65, and the drain is electrically connected to the source of PFETP3. The source of transistor T6 is electrically connected to the ground line 66, and the drain is electrically connected to the source of NFETN3.

The inverter circuit 54 includes NFETN4 and PFETP4. An enable signal OE is input to the gate of transistor T5, and a signal obtained by inverting the enable signal OE by the inverter circuit 54 is input to the gate of transistor T6. When the enable signal OE is at a low level, transistors T5 and T6 are turned on, and the inverter circuit 53 operates. When the enable signal OE is at a high level, transistors T5 and T6 are turned off, the inverter circuit 53 does not operate, and output node OUT has an input impedance.

The transistor T5 is the transistor Tr4 in the first embodiment and its modification, and the transistor T6 is the transistor Tr1 in the first embodiment and its modification. NFETN3 and N4 are the transistors Tr3 in the first embodiment and its modification, and PFETP3 and P4 are the transistors Tr2 in the first embodiment and its modification. As described above, the inverter circuit 53 has PFETP3 (transistor Tr2) and NFETN3 (transistor Tr3). Transistor T6 (transistor Tr1) is connected between NFETN3 and the ground line 66 (first power supply line), and the transistor T5 (transistor Tr4) is connected between PFETP3 and the power supply line 65 (second power supply line). Thus, the driving capability of the transistors T5 and T6 can be improved. Moreover, the chip size can be reduced.

The transistors Tr1 and Tr4 can be applied to circuits other than the second embodiment and its modification. In CFETs, the gate electrodes of NFETs and PFETS are common. Therefore, when the gate electrodes of NFETs and PFETs are electrically separated, the transistors Tr1 and Tr4 can be applied. In addition, high voltages (e.g., 2.5 V or more) may be used in an input/output circuit or an analog circuit. Therefore, the gate insulating films of the transistors Tr1 and Tr4 can be made thicker than those of the transistors Tr2 and Tr3, as in the third and fourth modification of the first embodiment. In addition, since the driving capability of the transistors Tr1 and Tr4 is approximately twice that of the transistors Tr2 and Tr3, the chip size can be reduced by using the transistors Tr1 and Tr4 for transistors with a large driving capability.

Further, the present invention is not limited to these embodiments, but various variations and modifications may be made without departing from the scope of the present invention.

What is claimed is:

1. A semiconductor device comprising:
a substrate; and
a first transistor including:
a first channel semiconductor layer of a first conductivity type, provided on the substrate;
a pair of first source and drain semiconductor layers of a second conductivity type different from the first conductivity type, provided on the substrate and sandwiching the first channel semiconductor layer;
a first gate electrode disposed between the pair of first source and drain semiconductor layers, the first gate electrode and the first channel semiconductor layer sandwiching a first gate insulating film;
a second channel semiconductor layer of the first conductivity type, provided over and spaced apart from the first channel semiconductor layer;
a pair of second source and drain semiconductor layers of the second conductivity type, provided over the pair of first source and drain semiconductor layers, electrically connected to the pair of first source and drain semiconductor layers, and sandwiching the second channel semiconductor layer; and
a second gate electrode disposed between the pair of second source and drain semiconductor layers, and electrically connected to the first gate electrode, the second gate electrode and the second channel semiconductor layer sandwiching a second gate insulating film.

2. The semiconductor device according to claim 1, further comprising:
a second transistor including:
a third channel semiconductor layer of a third conductivity type, which is either the first conductivity type or the second conductivity type, provided on the substrate;
a pair of third source and drain semiconductor layers of a fourth conductivity type different from the third conductivity type, provided on the substrate and sandwiching the third channel semiconductor layer; and
a third gate electrode disposed between the pair of third source and drain semiconductor layers, the third gate electrode and the third channel semiconductor layer sandwiching a third gate insulating film; and
a third transistor including:
a fourth channel semiconductor layer of the fourth conductivity type, provided over and spaced apart from the third channel semiconductor layer;
a pair of fourth source and drain semiconductor layers of the third conductivity type, provided over and spaced apart from the pair of third source and drain semiconductor layers and sandwiching the fourth channel semiconductor layer; and
a fourth gate electrode disposed between the pair of fourth source and drain semiconductor layers, and electrically connected to the third gate electrode, the fourth gate electrode and the fourth channel semiconductor layer sandwiching a fourth gate insulating film.

3. The semiconductor device according to claim 2, further comprising:
a fourth transistor including:
a fifth channel semiconductor layer of the second conductivity type, provided on the substrate;
a pair of fifth source and drain semiconductor layers of the first conductivity type, provided on the substrate and sandwiching the fifth channel semiconductor layer;
a fifth gate electrode disposed between the pair of fifth source and drain semiconductor layers, the fifth gate electrode and the fifth channel semiconductor layer sandwiching a fifth gate insulating film;
a sixth channel semiconductor layer of the second conductivity type, provided over and spaced apart from the fifth channel semiconductor layer;
a pair of sixth source and drain semiconductor layers of the second conductivity type, provided over the pair of fifth source and drain semiconductor layers, electrically connected to the pair of fifth source and drain semiconductor layers, and sandwiching the sixth channel semiconductor layer; and
a sixth gate electrode disposed between the pair of sixth source and drain semiconductor layers, and electrically connected to the fifth gate electrode, the sixth gate electrode and the sixth channel semiconductor layer sandwiching a sixth gate insulating film.

4. The semiconductor device according to claim 2, wherein an absolute value of a difference between a first height, which is a distance from the substrate to a farthest position in the second channel semiconductor layer, and a second height, which is a distance from the substrate to a farthest position in the fourth channel semiconductor layer, is less than or equal to 0.1 times the first height.

5. The semiconductor device according to claim 2, wherein:
a thickness of the third gate insulating film is greater than a thickness of the first gate insulating film;
the thickness of the third gate insulating film is greater than a thickness of the second gate insulating film;
a thickness of the fourth gate insulating film is greater than the thickness of the first gate insulating film; and
the thickness of the fourth gate insulating film is greater than the thickness of the second gate insulating film.

6. The semiconductor device according to claim 1, wherein the first channel semiconductor layer of the first transistor is in contact with the substrate.

7. The semiconductor device according to claim 2, wherein:
the first channel semiconductor layer and the second channel semiconductor layer have a fin structure, and the third channel semiconductor layer and the fourth channel semiconductor layer have a nanosheet structure;
the first channel semiconductor layer and the fourth channel semiconductor layer have the fin structure, and the third channel semiconductor layer and the second channel semiconductor layer have the nanosheet structure;
the third channel semiconductor layer and the second channel semiconductor layer have the fin structure, and the first channel semiconductor layer and the fourth channel semiconductor layer have the nanosheet structure; or
the third channel semiconductor layer and the fourth channel semiconductor layer have the fin structure, and the second channel semiconductor layer and the second channel semiconductor layer have the nanosheet structure.

8. The semiconductor device according to claim 2, comprising an SRAM cell, the SRAM cell including:
a bistable circuit including a pair of inverter circuits, the pair of inverter circuits including:
the second transistor; and
the third transistor, and
a passgate transistor that is the first transistor connected to a storage node of the bistable circuit.

9. The semiconductor device according to claim 3, comprising a transfer gate including the first transistor and the fourth transistor.

10. The semiconductor device according to claim 3, further comprising an inverter circuit including the second transistor and the third transistor, wherein:
the first transistor is connected between the third transistor and a first power supply line;
the fourth transistor is connected between the second transistor and a second power supply line; and
the third conductivity type includes a tri-state inverter of the second conductivity type.

11. A manufacturing method of a semiconductor device, the semiconductor device including:
a first transistor including:
a first channel semiconductor layer of a first conductivity type, provided on a substrate;
a pair of first source and drain semiconductor layers of a second conductivity type different from the first conductivity type, provided on the substrate and sandwiching the first channel semiconductor layer;
a first gate electrode disposed between the pair of first source and drain semiconductor layers, the first gate electrode and the first channel semiconductor layer sandwiching a first gate insulating film;
a second channel semiconductor layer of the first conductivity type, provided over and spaced apart from the first channel semiconductor layer;
a pair of second source and drain semiconductor layers of the second conductivity type, provided over the pair of first source and drain semiconductor layers, electrically connected to the pair of first source and drain semiconductor layers, and sandwiching the second channel semiconductor layer; and
a second gate electrode disposed between the pair of second source and drain semiconductor layers, and electrically connected to the first gate electrode, the second gate electrode and the second channel semiconductor layer sandwiching a second gate insulating film;
a second transistor including:
a third channel semiconductor layer of the second conductivity type, provided on the substrate;
a pair of third source and drain semiconductor layers of the first conductivity type, provided on the substrate and sandwiching the third channel semiconductor layer; and
a third gate electrode disposed between the pair of third source and drain semiconductor layers, the third gate electrode third and the channel semiconductor layer sandwiching a third gate insulating film; and
a third transistor including:
a fourth channel semiconductor layer of the first conductivity type, provided over and spaced apart from the third channel semiconductor layer;
a pair of fourth source and drain semiconductor layers of the second conductivity type, provided over and spaced apart from the pair of third source and drain semiconductor layers and sandwiching the fourth channel semiconductor layer; and
a fourth gate electrode disposed between the pair of fourth source and drain semiconductor layers, and electrically connected to the third gate electrode, the fourth gate electrode and the fourth channel semiconductor layer sandwiching a fourth gate insulating film,
the method comprising:
forming a first semiconductor layer on the substrate, a second semiconductor layer over and spaced apart from the first semiconductor layer, a third semiconductor layer on the substrate, and a fourth semiconductor layer over and spaced apart from the third semiconductor layer;
forming the pair of third source and drain semiconductor layers sandwiching the third semiconductor layer; and
simultaneously forming the pair of first source and drain semiconductor layers sandwiching the first semiconductor layer, the pair of second source and drain semiconductor layers sandwiching the second semiconductor layer, and the pair of fourth source and drain semiconductor layers sandwiching the fourth semiconductor layer.

12. A manufacturing method of a semiconductor device, the semiconductor device including:
a first transistor including:
a first channel semiconductor layer of a first conductivity type, provided on a substrate;
a pair of first source and drain semiconductor layers of a second conductivity type different from the first conductivity type, provided on the substrate and sandwiching the first channel semiconductor layer;
a first gate electrode disposed between the pair of first source and drain semiconductor layers, the first gate electrode and the first channel semiconductor layer sandwiching a first gate insulating film;
a second channel semiconductor layer of the first conductivity type, provided over and spaced apart from the first channel semiconductor layer;
a pair of second source and drain semiconductor layers of the second conductivity type, provided over the pair of first source and drain semiconductor layers, electrically connected to the pair of first source and drain semiconductor layers, and sandwiching the second channel semiconductor layer; and
a second gate electrode disposed between the pair of second source and drain semiconductor layers, and electrically connected to the first gate electrode, the second gate electrode and the second channel semiconductor layer sandwiching a second gate insulating film;
a second transistor including:
a third channel semiconductor layer of the first conductivity type, provided on the substrate;
a pair of third source and drain semiconductor layers of the second conductivity type, provided on the substrate and sandwiching the third channel semiconductor layer;
a third gate electrode disposed between the pair of third source and drain semiconductor layers, the third gate electrode and the third channel semiconductor layer sandwiching a third gate insulating film; and
a third transistor including:
a fourth channel semiconductor layer of the second conductivity type, provided over and spaced apart from the third channel semiconductor layer;
a pair of fourth source and drain semiconductor layers of the first conductivity type, provided over and spaced apart from the pair of third source and drain semiconductor layers and sandwiching the fourth channel semiconductor layer; and
a fourth gate electrode disposed between the pair of fourth source and drain semiconductor layers, and electrically connected to the third gate electrode, the fourth gate electrode and the fourth channel semiconductor layer sandwiching a fourth gate insulating film,
the method comprising:
forming a first semiconductor layer on the substrate, a second semiconductor layer over and spaced apart from the first semiconductor layer, a third semiconductor layer on the substrate, and a fourth semiconductor layer over and spaced apart from the third semiconductor layer;
simultaneously forming the pair of first source and drain semiconductor layers sandwiching the first semiconductor layer, the pair of second source and drain semiconductor layers sandwiching the second semiconductor layer, and the pair of third source and drain semiconductor layers sandwiching the third semiconductor layer; and
forming the pair of fourth source and drain semiconductor layers sandwiching the fourth semiconductor layer.

13. The manufacturing method of the semiconductor device according to claim 11, wherein:
the first semiconductor layer is the first channel semiconductor layer;
the second semiconductor layer is the second channel semiconductor layer;
the third semiconductor layer is the third channel semiconductor layer; and
the fourth semiconductor layer is the fourth channel semiconductor layer.

14. The manufacturing method of the semiconductor device according to claim 11, further comprising:
removing at least one semiconductor layer of the first semiconductor layer, the second semiconductor layer, the third semiconductor layer, and the fourth semiconductor layer, after forming the pair of first source and drain semiconductor layers, the pair of second source and drain semiconductor layers, the pair of third source and drain semiconductor layers, and the pair of fourth source and drain semiconductor layers; and
forming at least one channel semiconductor layer corresponding to the region where at least one semiconductor layer has been removed, including the first channel semiconductor layer, the second channel semiconductor layer, the third channel semiconductor layer, and the fourth channel semiconductor layer.
